(19) United States
(12) Patent Application Publication
(10) Pub. No.: US 2025/0372348 A1
(43) Pub. Date: Dec. 4, 2025

(54) RADIO-FREQUENCY POWER SOURCE AND PLASMA PROCESSING APPARATUS

(71) Applicants: Tokyo Electron Limited, Tokyo (JP); Fukuoka University, Fukuoka-shi (JP)

(72) Inventors: Kazushi KANEKO, Nirasaki City (JP); Satoru KAWAKAMI, Nirasaki City (JP); Shin OOWADA, Tokyo (JP); Ryo SHIMAZU, Nirasaki City (JP); Masahiro INOUE, Kurokawa-gun (JP); Tadashi SUETSUGU, Fukuoka-shi (JP)

(21) Appl. No.: 19/221,902

(22) Filed: May 29, 2025

(30) Foreign Application Priority Data
May 30, 2024 (JP) 2024-087817

(51) Int. Cl. H01J 37/32

(52) U.S. Cl. CPC H01J 37/32174

(57) ABSTRACT

A radio-frequency power source, includes: an amp unit including a gate terminal, a drain terminal, and a source terminal; an output terminal; an input power unit electrically connected to the gate terminal, configured to supply an input power to the amp unit, and configured to change frequencies in a frequency band in which the input power is can be supplied; a first setting unit, and configured to set a gate bias voltage of the amp unit; a second setting unit electrically connected to the drain terminal, and configured to set a drain bias voltage of the amp unit; and an instruction unit configured to output instruction values with which a radio-frequency power output from the output terminal is set for maximum efficiency to the input power unit, the first setting unit, and the second setting unit with respect to each of the frequencies in the frequency band.

### CROSS-REFERENCE TO RELATED APPLICATION

This application is based upon and claims the benefit of priority from Japanese Patent Application No. 2024-087817, filed on May 30, 2024, the entire contents of which are incorporated herein by reference.

### TECHNICAL FIELD

The present disclosure relates to a radio-frequency power source and a plasma processing apparatus.

### BACKGROUND

Patent Document 1 discloses “an EER system includes a phase component extractor configured to extract a phase component of an input radio-frequency modulation signal, an amplitude component extractor configured to extract an amplitude component of the radio-frequency modulation signal, a radio-frequency saturation amplifier configured to amplify a phase component signal from the phase component extractor, a voltage generator configured to generate a voltage corresponding to an amplitude component signal from the amplitude component extractor, a variable attenuator configured to adjust a level of the phase component signal input to the radio-frequency saturation amplifier, and a controller configured to adjust an output voltage of the voltage generator such that, by input of information with a desired output level, the corresponding output level is obtained, and control an attenuation amount of the variable attenuator such that the corresponding output voltage has an input level at which the radio-frequency saturation amplifier operates with optimal efficiency.”

### PRIOR ART DOCUMENTS

### Patent Documents

Patent Document 1: Japanese Patent Laid-Open Publication No. 2006-140911

### SUMMARY

According to one embodiment of the present disclosure, there is provided a radio-frequency power source, including: an amp unit including a gate terminal, a drain terminal, and a source terminal; an output terminal electrically connected to the drain terminal; an input power unit electrically connected to the gate terminal, configured to supply an input power to the amp unit, and configured to change frequencies in a frequency band in which the input power is can be supplied; a first setting unit electrically connected to the gate terminal, and configured to set a gate bias voltage of the amp unit; a second setting unit electrically connected to the drain terminal, and configured to set a drain bias voltage of the amp unit; and an instruction unit configured to output instruction values with which a radio-frequency power output from the output terminal is set for maximum efficiency to the input power unit, the first setting unit, and the second setting unit with respect to each of the frequencies in the frequency band.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an example of a configuration of a plasma processing apparatus according to an embodiment of the present disclosure.

FIG. 2 is a block diagram illustrating an example of a functional configuration of a first radio-frequency power source according to this embodiment.

FIG. 3 is a block diagram illustrating an example of connection in parameter setting.

FIG. 4 is a view illustrating an example of a parameter table according to the embodiment.

FIG. 5 is a view illustrating an example of a table that focuses on input powers Pᵢₙ for maximum efficiency with respect to frequencies in the parameter table.

FIG. 6 is a view illustrating an example of a table that focuses on power monitoring values P_{fm} for maximum efficiency with respect to frequencies in the parameter table.

FIG. 7 is a view illustrating an example of a correction table according to this embodiment.

FIG. 8 is a graph illustrating an example of a relationship between gate voltages V_{g} and efficiencies with respect to drain voltages Va at a central frequency.

FIG. 9 is a graph illustrating an example of a relationship between gate voltages V_{g} and outputs Pₒᵤₜ for maximum efficiency with respect to drain voltages Va at the central frequency.

FIG. 10 is a graph illustrating an example of a relationship between gate voltages V_{g} and input powers Pᵢₙ for the maximum efficiency with respect to drain voltages Va at the central frequency.

FIG. 11 is a graph illustrating an example of a relationship between input powers Pᵢₙ and efficiencies with respect to drain voltages Va at the central frequency.

FIG. 12 is a graph illustrating an example of a relationship between input powers Pᵢₙ and outputs Pₒᵤₜ with respect to drain voltages Va at the central frequency.

FIG. 13 is a graph illustrating an example of a relationship between drain voltages Va and outputs Pₒᵤₜ in a case where input power Pᵢₙ becomes constant and a case where input power Pᵢₙ is set for the maximum efficiency, at the central frequency.

FIG. 14 is a graph illustrating an example of a relationship between drain voltages Va and input power Pᵢₙ in a case where input power Pᵢₙ becomes constant and a case the input power Pᵢₙ is set for the maximum efficiency, at the central frequency.

FIG. 15 is a graph illustrating an example of a relationship between outputs Pₒᵤₜ and efficiencies in a case where drain voltage Va and input power Pᵢₙ vary, at the central frequency.

FIG. 16 is a graph illustrating an example of a relationship between input powers Pᵢₙ and efficiencies in frequency variation.

FIG. 17 is a graph illustrating an example of a relationship between frequencies and input powers Pᵢₙ.

FIG. 18 is a graph illustrating an example of a relationship between frequencies and the maximum efficiency.

FIG. 19 is a graph illustrating an example of a relationship between frequencies and outputs Pₒᵤₜ.

FIG. 20 is a graph illustrating an example of a relationship between frequencies and initial values of gate voltages V_{g}.

FIG. 21 is a graph illustrating an example of a relationship between drain voltages V_{d} and initial values of input powers Pᵢₙ with respect to frequencies.

FIG. 22 is a graph illustrating an example of a relationship between drain voltages V_{d} and efficiencies with respect to frequencies.

FIG. 23 is a view illustrating an example of a relationship between drain voltages V_{d} and efficiencies with respect to frequencies.

FIG. 24 is a graph illustrating an example of a relationship between drain voltages V_{d} and outputs Pₒᵤₜ with respect to frequencies.

FIG. 25 is a graph illustrating an example of a relationship between outputs Pₒᵤₜ and efficiencies with respect to frequencies.

FIG. 26 is a flowchart illustrating an example of a parameter generation processing according to this embodiment.

FIG. 27 is a flowchart illustrating an example of a correction value generation processing according to this embodiment.

FIG. 28 is a flowchart illustrating an example of a power control processing according to this embodiment.

FIG. 29 is a flowchart illustrating an example of an input power adjustment processing according to this embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, an embodiment of a radio-frequency power source and a plasma processing apparatus, which are disclosed herein, is described in detail based on the drawings. In addition, a disclosed technique is not limited to the following embodiment.

In a plasma processing apparatus, settings such as outputs and frequencies of a radio-frequency (RF) power source may be changed by process conditions. For example, it is conceivable that when load impedance of plasma is changed by the process conditions, the frequencies of the RF power source are changed to frequencies suitable for the load impedance. Further, in the RF power source, a switching lamp instead of a linear amp may be used so as to achieve efficiency of RF conversion. However, when the frequencies are changed, outputs of the RF power source may be reduced not to reach rated power. Further, when the frequencies are changed, in the switching amp used in the RF power source, an operating point for maximum efficiency is changed, and therefore, the efficiency may be reduced. Accordingly, it is expected to achieve both widening of a changeable frequency band and high efficiency in the frequency band.

### [Configuration of Plasma Processing Apparatus 1]

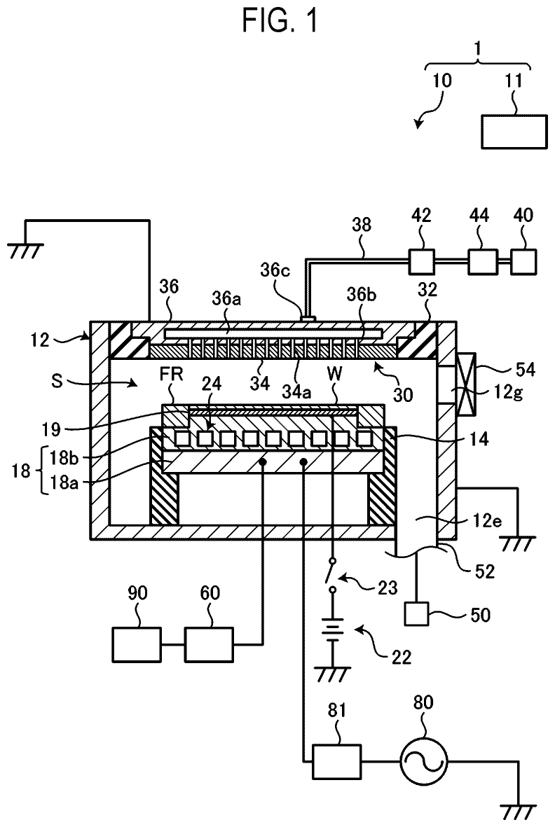

FIG. 1 is a schematic cross-sectional view illustrating an example of a configuration of a plasma processing apparatus according to an embodiment of the present disclosure. A plasma processing apparatus 1 shown in FIG. 1 is configured as a plasma processing apparatus using capacitively coupled plasma (CCP). The plasma processing apparatus 1 includes an apparatus main body 10 and a controller 11 that controls the whole of the plasma processing apparatus 1. Further, the apparatus main body 10 includes a substantially cylindrical processing container 12, a first radio-frequency power source 60, a second radio-frequency power source 80, and an upper controller 90.

An inner wall surface of the processing container 12 is made of, for example, an anodized aluminum. The processing container 12 is grounded for safety. A substantially cylindrical support 14 is provided on a bottom portion of the processing container 12. The support 14 is made of, for example, an insulating material. In the processing container 12, the support 14 extends vertically from the bottom portion of the processing container 12. Further, a lower electrode 18 serving as a stage of a substrate W is provided in the processing container 12. The lower electrode 18 is supported by the support 14. In addition, a wafer is an example of the substrate W.

The lower electrode 18 holds the substrate on an upper surface thereof. The lower electrode 18 includes a first plate 18a and a second plate 18b. The first plate 18a and the second plate 18b are made of, for example, a metal such as aluminum, and have a substantially disk shape. The second plate 18b is provided on the first plate 18a, and is electrically connected to the first plate 18a.

An electrostatic chuck 19 is provided on the second plate 18b of the lower electrode 18. The electrostatic chuck 19 has a structure in which an electrode as a conductive film is interposed between a pair of insulating layers or insulating sheets. A direct current power source 22 is electrically connected to the electrode of the electrostatic chuck 19 via a switch 23. The electrostatic chuck 19 attracts the substrate W by an electrostatic force such as a Coulomb force generated by a direct current from the direct current power source 22. Accordingly, the electrostatic chuck 19 is capable of holding the substrate W.

On a peripheral edge portion of the second plate 18b of the lower electrode 18, a focus ring FR is disposed to surround an edge of the substrate W and the electrostatic chuck 19. The focus ring FR is provided to improve uniformity of etching. The focus ring FR is made of a material selected based on a material of a film to be etched, and is made of, for example, quartz. Further, the focus ring FR is an example of an edge ring.

A coolant flow path 24 is provided inside the second plate 18b. The coolant flow path 24 constitutes a temperature adjustment mechanism. A heat-transfer fluid such as brine or gas flows in the coolant flow path 24. For example, a coolant supplied from a chiller unit provided outside the processing container 12 is circulated in the coolant flow path 24. A temperature of the coolant is controlled, so that a temperature of the substrate W supported by the electrostatic chuck 19 is controlled. In addition, the lower electrode 18 may include a heat-transfer gas supply configured to supply a heat-transfer gas to a gap between a rear surface of the substrate W and an upper surface of the electrostatic chuck 19.

In addition, the apparatus main body 10 includes an upper electrode 30. Above the lower electrode 18, the upper electrode 30 is disposed to face the lower electrode 18. The lower electrode 18 and the upper electrode 30 are provided substantially in parallel to each other. A processing space S for performing a plasma processing on the substrate W is provided between the upper electrode 30 and the lower electrode 18.

The upper electrode 30 is supported in an upper portion of the processing container 12 via an insulating shielding member 32. Further, the upper electrode 30 is connected to GND. The upper electrode 30 may include an electrode plate 34 and an electrode support 36. The electrode plate 34 faces the processing space S, and a plurality of gas discharge holes 34a is formed in the electrode plate 34. The electrode plate 34 is made of, for example, silicon.

The electrode support 36 detachably supports the electrode plate 34, and may be made of, for example a conductive material such as aluminum. The electrode support 36 may have a water cooling structure. A gas diffusion chamber 36a is provided inside the electrode support 36. From the gas diffusion chamber 36a, a plurality of gas passage holes 36b communicating with the gas discharge holes 34a extends downward. Further, a gas introduction port 36c that guides a processing gas to the gas diffusion chamber 36a is formed in the electrode support 36, and a gas supply pipe 38 is connected to the gas introduction port 36c.

A gas source group 40 is connected to the gas supply pipe 38 via a valve group 42 and a flow rate controller group 44. The gas source group 40 includes a plurality of gas sources such as a source of fluorocarbon gas, a source of a rare gas (noble gas), and a source of oxygen (O₂). The fluorocarbon gas is, for example, a gas including at least one of C₄F₆ gas or C₄F₈ gas. Further, the rare gas is a gas including at least one of various rare gases such as Ar gas and He gas.

The valve group 42 includes a plurality of valves, and the flow rate controller group 44 includes a plurality of flow rate controllers such as mass flow controllers. Each of the plurality of gas sources of the gas source group 40 is connected to the gas supply pipe 38 via a corresponding valve of the valve group 42 and a corresponding flow rate controller of the flow rate controller group 44.

An exhaust port 12e is provided at a bottom portion of the processing container 12. An exhaust device 50 is connected to the exhaust port 12e via an exhaust pipe 52. The exhaust device 50 has a vacuum pump such as a turbo molecular pump to depressurize a space of the processing container 12 to a desired vacuum degree. A loading/unloading port 12g of the substrate W is provided in a sidewall of the processing container 12. Further, the loading/unloading port 12g is capable of being opened/closed by a gate valve 54.

The controller 11 includes a memory, a processor, and an input/output interface. The computer readable memory stores programs executed by the processor and recipes including conditions for each process. The processor executes a program read from the memory, and controls each part of the plasma processing apparatus 1 through the input/output interface, based on the recipes stored in the memory.

For example, the controller 11 controls each part of the plasma processing apparatus 1 to perform a power control method which will be described later. As a specific example, the controller 11 controls the first radio-frequency power source 60 to read parameters corresponding to neighboring frequencies and neighboring powers from a parameter table that stores parameters of an amp unit to be described later, based on a set frequency F and a set power P_{f}. The controller 11 controls the first radio-frequency power source 60 to calculate and set parameters corresponding to the set frequency F and the set power P_{f} from neighboring parameters, and start output of radio-frequency power. The controller 11 controls the first radio-frequency power source 60 to read correction values k corresponding to neighboring frequencies and neighboring powers from a correction table, based on the set frequency F and the set power P_{f}. The controller 11 controls the first radio-frequency power source 60 to calculate correction values k corresponding to the set frequency F and the set power P_{f} from neighboring correction values, and calculate a power monitoring value P_{fm}, based on the correction values k and progressive wave power P_{fd}. The controller 11 controls the first radio-frequency power source 60 to adjust the parameters of the amp unit such that the set power P_{f} and the power monitoring value P_{fm} match each other.

The first radio-frequency power source 60 outputs radio-frequency power of a specific frequency in an available output frequency band. That is, the first radio-frequency power source 60 generates a radio frequency for plasma generation. The first radio-frequency power source 60 outputs, for example, radio-frequency power of a specific frequency in a frequency band in which a center frequency is 220 MHz. A set frequency F and set power P_{f} of radio-frequency power are input to the first radio-frequency power source 60 from the upper controller 90 which will be described later. Further, the radio-frequency power output from the first radio-frequency power source 60 is supplied to the lower electrode 18. Further, the radio-frequency power output from the first radio-frequency power source 60 may be supplied to the upper electrode 30.

The second radio-frequency power source 80 generates a radio frequency for drawing ions into the substrate W. The second radio-frequency power source 80 generates a radio frequency lower than a radio frequency generated by the first radio-frequency power source 60. The second radio-frequency power source 80 generates, for example, a radio frequency of 600 kHZ. Hereinafter, in order to distinguish the radio frequency generated by the first radio-frequency power source 60 from the radio frequency generated by the second radio-frequency power source 80, the radio frequency generated by the second radio-frequency power source 80 is referred to as a “radio frequency for bias.” The second radio-frequency power source 80 is connected to the lower electrode 18 via a matcher 81. The matcher 81 matches output impedance of the second radio-frequency power source 80 and input impedance at a load side (a side of the lower electrode 18). Further, the second radio-frequency power source 80 and the matcher 81, which are used at the radio frequency for bias, may be an additional radio-frequency power source 60′, which is provided separately from the first radio-frequency power source 60 and capable of changing frequency.

The upper controller 90 is a controller that controls the first radio-frequency power source 60 according to an instruction of the controller 11. The upper controller 90 outputs a setting frequency F and a set power P_{f} of radio-frequency power to the first radio-frequency power source 60 according to a recipe input from the controller 11. Further, a power monitoring value P_{fm} to be described later is input to the upper controller 90 from the first radio-frequency power source 60. The upper controller 90 outputs the input power monitoring value P_{fm} to the controller 11. Further, the upper controller 90 may be included in the controller 11.

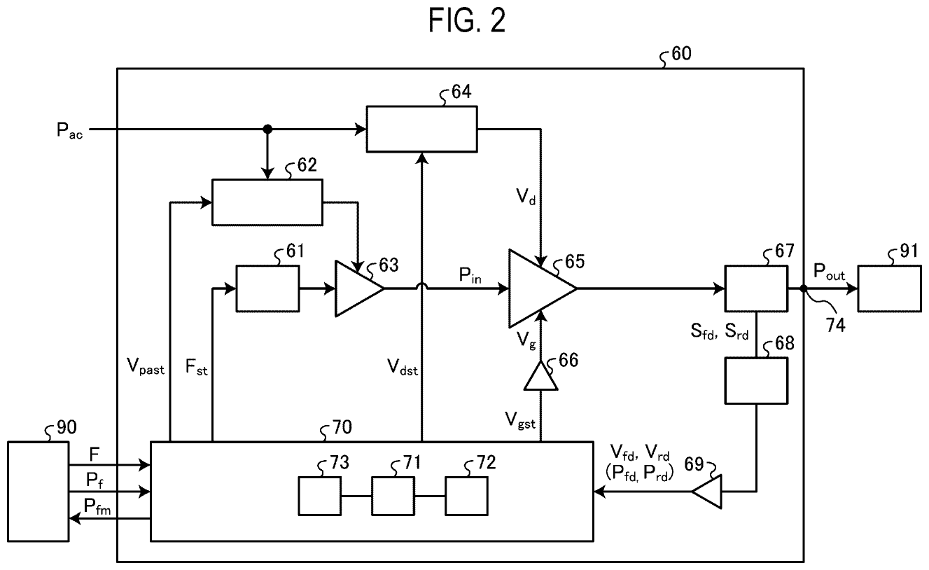

Next, details of the first radio-frequency power source 60 is described with reference to FIG. 2. FIG. 2 is a block diagram illustrating an example of a functional configuration of the first radio-frequency power source according to this embodiment. As illustrated in FIG. 2, the first radio-frequency power source 60 includes a direct digital synchronizer (DDS) 61, a first variable direct current (DC) voltage source 62, a preamp 63, a second variable DC voltage source 64, a main amp 65, a buffer amp 66, a directional coupler 67, a wave detector 68, a buffer amp 69, and a controller 70. Further, the controller 70 includes a processor 71, a storage 72, and an input/output unit 73. A parameter table and a correction table, which will be described later, are stored in the storage 72. Further, an output terminal 74 of the first radio-frequency power source 60 is connected to the lower electrode 18 (a plasma load 91). Further, a matcher which is not illustrated may be provided between the output terminal 74 and the lower electrode 18.

The DDS 61 is a direct digital synthesizing oscillator, and generates a radio-frequency signal of an arbitrary set frequency F based on a frequency set value Fₛₜ input from the controller 70. Further, the frequency set value Fₛₜ includes, for example, a frequency, an amplitude (waveform data) or the like of a radio-frequency signal to be generated are included. The generated radio-frequency signal is output to the preamp 63. Here, the generated radio-frequency signal is, for example, a sine wave. Further, the DDS 61 may be of another type, for example, a VF converter (voltage controlled frequency generator) or the like as long as it can generate the radio-frequency signal of the set frequency F.

The first variable DC voltage source 62 is a direct current power source by which a voltage is variable, and supplies power to the preamp 63. A commercial power source is connected to the first variable DC voltage source 62 to supply alternating current (AC) input Pac. Based on an input power set value Vₚₐₛₜ input from the controller 70, a voltage that the first variable DC voltage source 62 supplies to the preamp 63 is controlled, and power that the first variable DC voltage source 62 supplies to the preamp 63 is controlled. The first variable DC voltage source 62 may supply, for example, power of about 50 dBm (100 W) to the preamp 63.

The preamp 63 amplifies the radio-frequency signal input from the DDS 61 and outputs, to the main amp 65, the amplified radio-frequency signal as input power Pᵢₙ of the main amp 65. Output of the preamp 63, i.e., the input power Pᵢₙ is controlled by the voltage supplied from the first variable DC voltage source 62. The input power Pᵢₙ is, for example, about 50 dBm (100 W). That is, the DDS 61, the first variable DC voltage source 62, and the preamp 63 constitute an input power unit. That is, the input power unit is electrically connected to a transistor gate terminal of the main amp 65, and is configured to supply the input power Pᵢₙ to the main amp 65 and be capable of changing a frequency supplied in a frequency band in which the input power Pᵢₙ is capable of being supplied.

The second variable DC voltage source 64 is a direct current power source by which a voltage is variable, and supplies power to the main amp 65. A commercial power source is connected to the second variable DC voltage source 64 to supply the AC input P_{dc}. Based on a drain voltage set value V_{dst} input from the controller 70, a drain bias voltage V_{d} that the second variable DC voltage source 64 supplies to the main amp 65 is controlled, and power supplied to the main amp 65 is controlled. That is, the second variable DC voltage source 64 is an example of a second setting unit electrically connected to a drain terminal of the main amp 65, and is configured to set the drain bias voltage V_{d} of the main amp 65 (the amp unit). In the following description, the drain bias voltage V_{d} may be represented as a drain voltage V_{d}. The second variable DC voltage source 64 may supply, for example, power of about 3000 W to the main amp 65.

The main amp 65 amplifies the input power Pᵢₙ as the input radio-frequency signal, which is input from the preamp 63, to a target value or more and outputs the amplified input power Pᵢₙ to the directional coupler 67. The main amp 65 is an example of a switching amplification circuit, and includes a field effect transistor (FET) including a gate terminal, a drain terminal, and a source terminal. Further, the FET is an example of a transistor. That is, the main amp 65 is an example of an amp unit including a gate terminal, a drain terminal, and a source terminal. Further, the main amp 65 is a switching amp (switching amplification circuit) of which an operation becomes a class E operation in which an FET is operated by zero-cross switching.

The preamp 63 of the above-described input power unit and the buffer amp 66 that sets a gate bias voltage V_{g} of the FET are electrically connected to the gate terminal of the main amp 65. A gate voltage set value V_{gst} is input to the buffer amp 66 from the controller 70. That is, the buffer amp 66 is an example of a first setting unit electrically connected to the gate terminal of the main amp 65, and is configured to set the gate bias voltage V_{g} of the main amp 65 (the amp unit). In the following description, the gate bias voltage V_{g} may be represented as a gate voltage V_{g}.

Output of the main amp 65, i.e., output Pₒᵤₜ output from the output terminal 74 via the directional coupler 67 is controlled by the input power Pᵢₙ, the gate voltage V_{g}, and the drain voltage V_{d} of the main amp 65 (the FET). Further, the output terminal 74 is electrically connected to the drain terminal. In an available output frequency band, the output Pₒᵤₜ is, for example, preferably 2000 W or more, and more preferably 2200 W.

In addition, in an ideal operation of the above-described zero-cross switching, switching is made at a timing at which at least one of the drain voltage V_{d} or a drain current I_{d} of the FET becomes zero, and therefore, loss of the FET, which is almost equal to V_{d}×I_{d}, becomes zero. In this case, drain efficiency η₁ becomes 100% as a theoretical value. However, in practice, it is difficult that the loss of the FET becomes zero due to a frequency characteristic of the FET, and the like. On the other hand, in this embodiment, the input power Pᵢₙ, the drain voltage V_{d}, and the gate voltage V_{g} of the FET in the zero-cross switching are adjusted depending on a frequency, thus achieving both high efficiency and widening of a frequency band.

The directional coupler 67 is provided on a transmission route between the main amp 65 and the lower electrode 18 to extract progressive wave power P_{fd} and reflected wave power P_{rd}. That is, the directional coupler 67 is provided between the drain terminal and the output terminal 74. In addition, in FIG. 2, the side of the lower electrode 18 is represented as the plasma load 91. A progressive wave signal S_{fd} and a reflected wave signal S_{rd}, which become extracted weak signals, are input to the wave detector 68.

The wave detector 68 detects the progressive wave signal S_{fd} and the reflected wave signal S_{rd}, which are input from the directional coupler 67. The wave detector 68 outputs a progressive wave voltage V_{fd} and a reflected wave voltage V_{rd} after the wave detection to the controller 70 via the buffer amp 69.

The controller 70 controls each unit in the first radio-frequency power source 60. The set frequency F and the set power P_{f} of the radio-frequency power are input to the controller 70 from the upper controller 90. Further, the progressive wave voltage V_{fd} and the reflected wave voltage V_{rd} are input to the controller 70 from the wave detector 68 via the buffer amp 69. In the controller 70, the set frequency F, the set power P_{f}, the progressive wave voltage V_{fd}, and the reflected wave voltage V_{rd} are input to the processor 71 via the input/output unit 73, and the progressive wave voltage V_{fd} and the reflected wave voltage V_{rd} are converted into the progressive wave power P_{fd} and the reflected wave power P_{rd}, respectively.

Meanwhile, from the processor 71, the frequency set value Fₛₜ and the input power set value Vₚₐₛₜ are respectively output to the DDS 61 and the first variable DC voltage source via the input/output unit 73. Further, from the processor 71, the drain voltage set value V_{dst} and the gate voltage set value V_{gst} are respectively output to the second variable DC voltage source 64 and the buffer amp 66 via the input/output unit 73.

That is, for each set frequency F, the controller 70 outputs an instruction value with which radio-frequency power output from the output terminal 74 is set for maximum efficiency to the DDS 61, the first variable DC voltage source 62, the second variable DC voltage source 64, and the buffer amp 66. That is, the frequency set value Fₛₜ, the input power set value Vₚₐₛₜ, the drain voltage set value V_{dst}, and the gate voltage set value V_{gst} are examples of the instruction value, and are examples of parameters of the switching amplification circuit. Further, the processor 71 outputs a power monitoring value P_{fm} to the upper controller 90 via the input/output unit 73.

In other words, the controller 70 is an example of an instruction unit configured to, for each frequency in a frequency band, output an instruction value with which radio-frequency power output from the output terminal 74 is set for maximum efficiency to the input power unit, the first setting unit, and the second setting unit. That is, the controller 70 controls parameters of the switching amplification circuit such that in an available output frequency band, the radio-frequency power is set to a target value or more for each specific frequency. As will be described later, with reference to the storage 72 that stores and correlates input powers Pᵢₙ with which the radio-frequency power is set for the maximum efficiency with a plurality of drain bias voltages V_{d}, respectively, the controller 70 outputs an instruction value to the input power unit, the first setting unit, and the second setting unit. That is, as will be described later, with reference to the storage 72 that stores and correlates input powers Pᵢₙ with which the radio-frequency power is set for the maximum efficiency with a plurality of drain bias voltages V_{d}, respectively, the controller 70 controls the input power Pᵢₙ, the gate bias voltage V_{g}, and the drain bias voltage V_{d}.

As will be described later, the storage 72 stores and correlates a plurality of frequencies of the input power Pᵢₙ with gate bias voltages V_{g} with which the radio-frequency power is set to the target value or greater with respect to the frequencies, a plurality of drain bias voltages V_{d}, input powers Pᵢₙ with which the radio-frequency power is set for maximum efficiency with respect to the drain bias voltages V_{d}, and a plurality of set powers of the radio-frequency power, which correlates to the input powers Pᵢₙ, respectively. With reference to the storage 72, the controller 70 outputs an instruction value to the input power unit, the first setting unit, and the second setting unit. Further, as will be described later, the controller 70 calculates instruction values for the input power unit, the first setting unit, and the second setting unit by proportionally dividing neighboring discrete values from frequencies, gate bias voltages V_{g}, drain bias voltages V_{d}, input powers Pᵢₙ, and set powers P_{f}, which are stored as discrete values in the storage 72, and the controller 70 outputs the calculated instruction values.

As will be described later, the storage 72 stores and correlates correction values k of the radio-frequency power with a plurality of frequencies of the input power Pᵢₙ and a plurality of set powers P_{f} of the radio-frequency power, respectively. With reference to the storage 72, the controller 70 calculates a power monitoring value P_{fm} based on the progressive wave power P_{fd} output from the directional coupler 67 and the correction value k, and the controller 70 outputs instruction values to the input power unit and the second setting unit such that the calculated power monitoring value P_{fm} and current set power P_{f} of the radio-frequency power match each other. Further, as will be described later, the controller 70 calculates instruction values for the input power unit and the second setting unit by proportionally dividing neighboring discrete values from the frequency setting power P_{f} and the correction value k, which are stored as discrete values in the storage 72, and the controller 70 outputs the calculated instruction values. Further, like processing of the progressive wave power P_{fd}, the controller 70 also calculates reflected wave power P_{rd}.

### [Parameter Table and Correction Table]

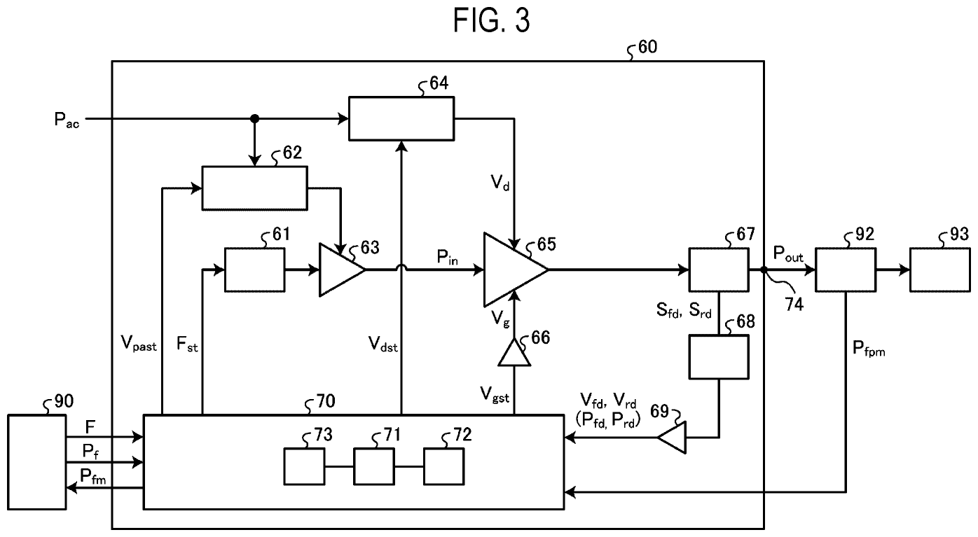

Next, with reference to FIGS. 3 to 7, a parameter table and a correction table, which are stored in the storage 72, are described. FIG. 3 is a block diagram illustrating an example of connection in parameter setting. In generation of a parameter table and a correction table, i.e., parameter setting, as illustrated in FIG. 3, a power meter 92 and a dummy load 93 are connected to the output terminal 74 of the first radio-frequency power source 60. Further, a power meter value P_{fpm} which is a measurement value of the power meter 92 is input to the controller 70.

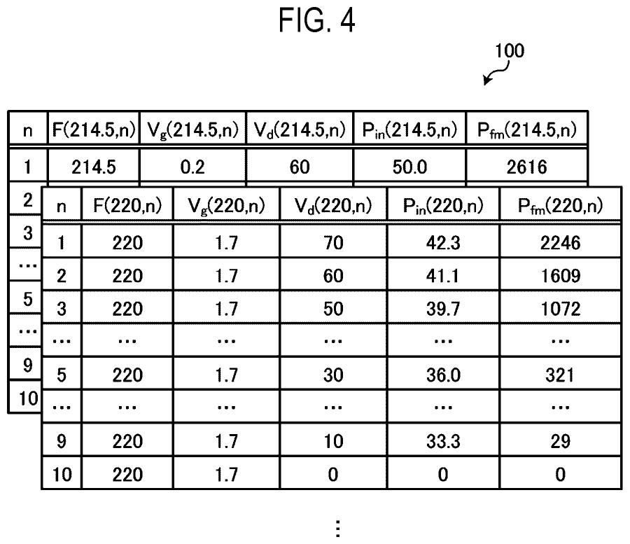

FIG. 4 is a view illustrating an example of a parameter table according to this embodiment. A parameter table 100 shown in FIG. 4 stores parameters with which rated power is obtained with respect to output Pₒᵤₜ of radio-frequency power, and the output Pₒᵤₜ of the radio-frequency power is set for maximum efficiency. The rated power is, for example, 2000 W. The parameter table 100 includes, for example, tables with respect to a plurality of discrete frequencies in an available output frequency band. The plurality of discrete frequencies may be, for example, set frequencies F. The tables are provided, for example, with respect to frequencies such as 209 MHz, 214.5 MHz, 220 MHz, 225.5 MHz, and 231 MHz.

For example, the table of 220 MHz has items such as “n,” “F(220, n),” “V_{g}(220, n),” “V_{d}(220, n),” “Pᵢₙ(220, n),” “P_{fm}(220, n).”

“n” represents a number of discrete values of each parameter in each frequency. “F(220, n)” represents a set frequency F in the number “n” of discrete values. Further, “F(220, n)” becomes 220 with respect to all numbers “n” of discrete values in the table of 220 MHz. “V_{g}(220, n)” represents a gate voltage V_{g} in the number “n” of discrete values. Further, since “V_{g}(220, n)” is set as an initial value for each set frequency F, “V_{g}(220, n)” becomes the same value, e.g., “1.7” with respect to all numbers “n” of discrete values in the table of 220 MHz.

“V_{d}(220, n)” represents a drain voltage V_{d} in the number “n” of discrete values. “Pᵢₙ(220, n)” represents input power Pᵢₙ in the number “n” of discrete values. “P_{fm}(220, n)” represents a power monitoring value P_{fm} in the number “n” of discrete values.

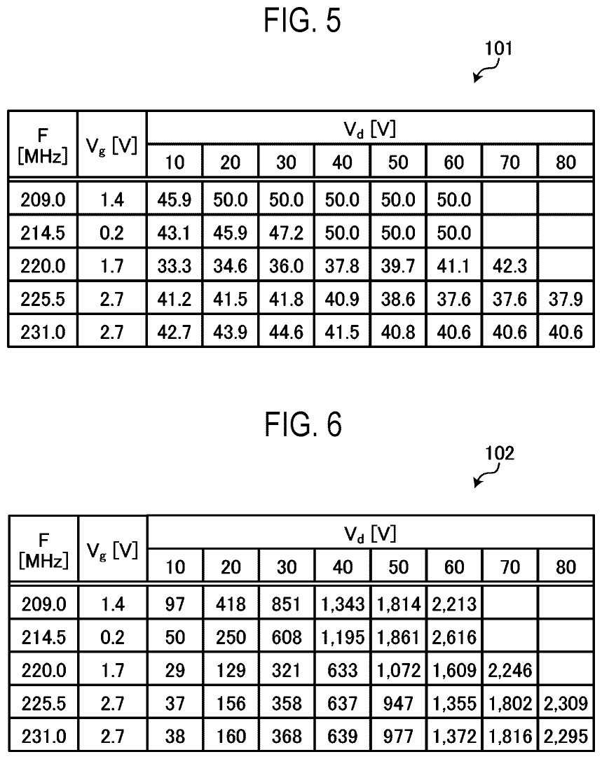

FIG. 5 is a view illustrating an example of a table that focuses on input powers Pᵢₙ for the maximum efficiency with respect to frequencies in the parameter table. A table 101 shown in FIG. 5 is an example of a table that focuses on input powers Pᵢₙ for the maximum efficiency with respect to frequencies in the parameter table 100. For example, when the set frequency F is 209.0 MHz, at a gate voltage V_{g} of 1.4 V, the input power Pᵢₙ becomes 45.9 dBm at a drain voltage V_{d} of 10 V, and becomes 50.0 dBm at drain voltages V_{d} of 20 V, 30 V, 40 V, 50 V, and 60V. Further, a blank of the input power Pᵢₙ represents that the input power Pᵢₙ is not set at the drain voltage V_{d}.

Similarly, for example, when the set frequency Fis 214.5 MHZ, at a gate voltage V_{g} of 0.2 V, the input power Pᵢₙ becomes 43.1 dBm at the drain voltage V_{d} of 10 V, becomes 45.9 dBm at the drain voltage V_{d} of 20 V, and becomes 47.2 dBm at the drain voltage V_{d} of 30 V. Further, the input power Pᵢₙ becomes 50.0 dBm at the drain voltages V_{d} of 40 V, 50 V, and 60V.

For example, when the set frequency F is 220.0 MHZ, at a gate voltage V_{g} of 1.7 V, the input power Pᵢₙ becomes 33.3 dBm at the drain voltage V_{d} of 10 V, becomes 34.6 dBm at the drain voltage V_{d} of 20 V, and becomes 36.0 dBm at the drain voltage V_{d} of 30 V. Further, the input power Pᵢₙ becomes 37.8 dBm at the drain voltage V_{d} of 40 V, becomes 39.7 dBm at the drain voltage V_{d} of 50 V, becomes 41.1 dBm at the drain voltage V_{d} of 60 V, and becomes 42.3 dBm at a drain voltage V_{d} of 70V.

For example, when the set frequency Fis 225.5 MHZ, at a gate voltage V_{g} of 2.7 V, the input power Pᵢₙ becomes 41.2 dBm at the drain voltage V_{d} of 10 V, becomes 41.5 dBm at the drain voltage V_{d} of 20 V, and becomes 41.8 dBm at the drain voltage V_{d} of 30 V. Further, the input power Pᵢₙ becomes 40.9 dBm at the drain voltage V_{d} of 40 V, becomes 38.6 dBm at the drain voltage V_{d} of 50 V, becomes 37.6 dBm at the drain voltage V_{d} of 60 V, becomes 37.6 dBm at the drain voltage V_{d} of 70V, and becomes 37.9 dBm at a drain voltage V_{d} of 80V.

For example, when the set frequency Fis 231.0 MHZ, at the gate voltage V_{g} of 2.7 V, the input power Pᵢₙ becomes 42.7 dBm at the drain voltage V_{d} of 10 V, becomes 43.9 dBm at the drain voltage V_{d} of 20 V, and becomes 44.6 dBm at the drain voltage V_{d} of 30 V. Further, the input power Pᵢₙ becomes 41.5 dBm at the drain voltage V_{d} of 40 V, becomes 40.8 dBm at the drain voltage V_{d} of 50 V, becomes 40.6 dBm at the drain voltage V_{d} of 60 V, becomes 40.6 dBm at the drain voltage V_{d} of 70V, and becomes 40.6 dBm at the drain voltage V_{d} of 80V.

FIG. 6 is a view illustrating an example of a table that focuses on power monitoring values P_{fm} for the maximum efficiency with respect to frequencies in the parameter table. A table 102 shown in FIG. 6 is an example of a table that focuses on power monitoring values P_{fm} for the maximum efficiency with respect to frequencies in the parameter table 100. At this time, the input powers Pᵢₙ with respect to the set frequencies F, the gate voltages V_{g}, and the drain voltages V_{d} correspond to the numerical values of FIG. 5. For example, when the set frequency F is 209.0 MHz, at the gate voltage V_{g} of 1.4 V, the power monitoring value P_{fm} becomes 97 W when the drain voltage V_{d} is 10 V and the input power Pᵢₙ is 45.9 dBm, becomes 418 W when the drain voltage V_{d} is 20 V and the input power Pᵢₙ is 50.0 dBm, and becomes 851 W when the drain voltage V_{d} is 30 V and the input power Pᵢₙ is 50.0 dBm. Further, the power monitoring value P_{fm} becomes 1343 W when the drain voltage V_{d} is 40 V and the input power Pᵢₙ is 50.0 dBm, becomes 1814 W when the drain voltage V_{d} is 50 V and the input power Pᵢₙ is 50.0 dBm, and becomes 2213 W when the drain voltage V_{d} is 60 V and the input power Pᵢₙ is 50.0 dBm. Further, a blank of the power monitoring value P_{fm} represents that the power monitoring value P_{fm} is not set at the drain voltage V_{d}.

Similarly, for example, when the set frequency Fis 214.5 MHZ, at the gate voltage V_{g} of 0.2 V, the power monitoring value P_{fm} becomes 50 W when the drain voltage V_{d} is 10 V and the input power Pᵢₙ is 43.1 dBm, becomes 250 W when the drain voltage V_{d} is 20 V and the input power Pᵢₙ is 45.9 dBm, and becomes 608 W when the drain voltage V_{d} is 30 V and the input power Pᵢₙ is 47.2 dBm. Further, the power monitoring value P_{fm} becomes 1195 W when the drain voltage V_{d} is 40 V and the input power Pᵢₙ is 50.0 dBm, becomes 1861 W when the drain voltage V_{d} is 50 V and the input power Pᵢₙ is 50.0 dBm, and becomes 2616 W when the drain voltage V_{d} is 60 V and the input power Pᵢₙ is 50.0 dBm.

For example, when the set frequency F is 220.0 MHZ, at the gate voltage V_{g} of 1.7 V, the power monitoring value P_{fm} becomes 29 W when the drain voltage V_{d} is 10 V and the input power Pᵢₙ is 33.3 dBm, becomes 129 W when the drain voltage V_{d} is 20 V and the input power Pᵢₙ is 34.6 dBm, and becomes 321 W when the drain voltage V_{d} is 30 V and the input power Pᵢₙ is 36.0 dBm. Further, the power monitoring value P_{fm} becomes 633 W when the drain voltage V_{d} is 40 V and the input power Pᵢₙ is 37.8 dBm, becomes 1072 W when the drain voltage V_{d} is 50 V and the input power Pᵢₙ is 39.7 dBm, becomes 1609 W when the drain voltage V_{d} is 60 V and the input power Pᵢₙ is 41.1 dBm, and becomes 2246 W when the drain voltage V_{d} is 70 V and the input power Pᵢₙ is 42.3 dBm.

For example, when the set frequency Fis 225.5 MHZ, at the gate voltage V_{g} of 2.7 V, the power monitoring value P_{fm} becomes 37 W when the drain voltage V_{d} is 10 V and the input power Pᵢₙ is 41.2 dBm, becomes 156 W when the drain voltage V_{d} is 20 V and the input power Pᵢₙ is 41.5 dBm, and becomes 358 W when the drain voltage V_{d} is 30 V and the input power Pᵢₙ is 41.8 dBm. Further, the power monitoring value P_{fm} becomes 637 W when the drain voltage V_{d} is 40 V and the input power Pᵢₙ is 40.9 dBm, becomes 947 W when the drain voltage V_{d} is 50 V and the input power Pᵢₙ is 38.6 dBm, becomes 1355 W when the drain voltage V_{d} is 60 V and the input power Pᵢₙ is 37.6 dBm, becomes 1802 W when the drain voltage V_{d} is 70 V and the input power Pᵢₙ is 37.6 dBm, and becomes 2309 W when the drain voltage V_{d} is 80 V and the input power Pᵢₙ is 37.9 dBm.

For example, when the set frequency F is 231.0 MHZ, at the gate voltage V_{g} of 2.7 V, the power monitoring value P_{fm} becomes 38 W when the drain voltage V_{d} is 10 V and the input power Pᵢₙ is 42.7 dBm, becomes 160 W when the drain voltage V_{d} is 20 V and the input power Pᵢₙ is 43.9 dBm, and becomes 368 W when the drain voltage V_{d} is 30 V and the input power Pᵢₙ is 44.6 dBm. Further, the power monitoring value P_{fm} becomes 639 W when the drain voltage V_{d} is 40 V and the input power Pᵢₙ is 41.5 dBm, becomes 977 W when the drain voltage V_{d} is 50 V and the input power Pᵢₙ is 40.8 dBm, becomes 1372 W when the drain voltage V_{d} is 60 V and the input power Pᵢₙ is 40.6 dBm, becomes 1816 W when the drain voltage V_{d} is 70 V and the input power Pᵢₙ is 40.6 dBm, and becomes 2295 W when the drain voltage V_{d} is 80 V and the input power Pᵢₙ is 40.6 dBm.

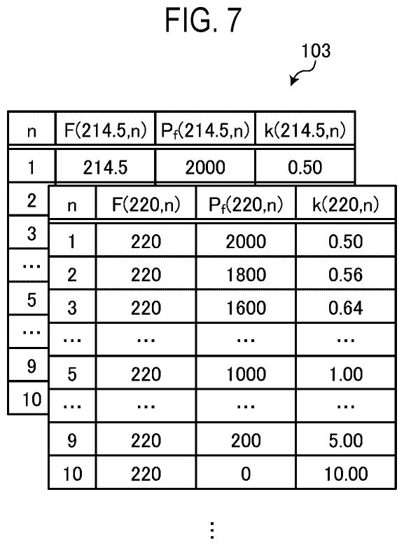

FIG. 7 is a view illustrating an example of a correction table according to this embodiment. A correction table 103 shown in FIG. 7 stores correction values k with respect to set powers P_{f} at set frequencies F. The correction table 103 includes, for example, tables with respect to a plurality of discrete frequencies in an available output frequency band. The plurality of discrete frequencies may be, for example, the set frequencies F. The tables are provided, for example, with respect to frequencies such as 209 MHZ, 214.5 MHz, 220 MHZ, 225.5 MHz, and 231 MHz.

For example, the table of 220 MHz has items such as “n,” “F(Fₛₜ, n),” “P_{f}(Fₛₜ, n),” and “k(Fₛₜ, n).” “n” represents a number of discrete values of a correction value k in each frequency. “F(Fₛₜ, n)” represents a set frequency F (frequency set value Fₛₜ) in the number “n” of discrete values. Further, “F(Fₛₜ, n)” becomes 220 with respect to all numbers “n” of discrete values in the table of 220 MHZ. “P_{f}(Fₛₜ, n)” represents set power P_{f} in the number “n” of discrete values. “k(Fₛₜ, n)” represents a correction value k corresponding to the set power P_{f} in the number “n” of discrete values.

### [Calculation Examples of Parameters]

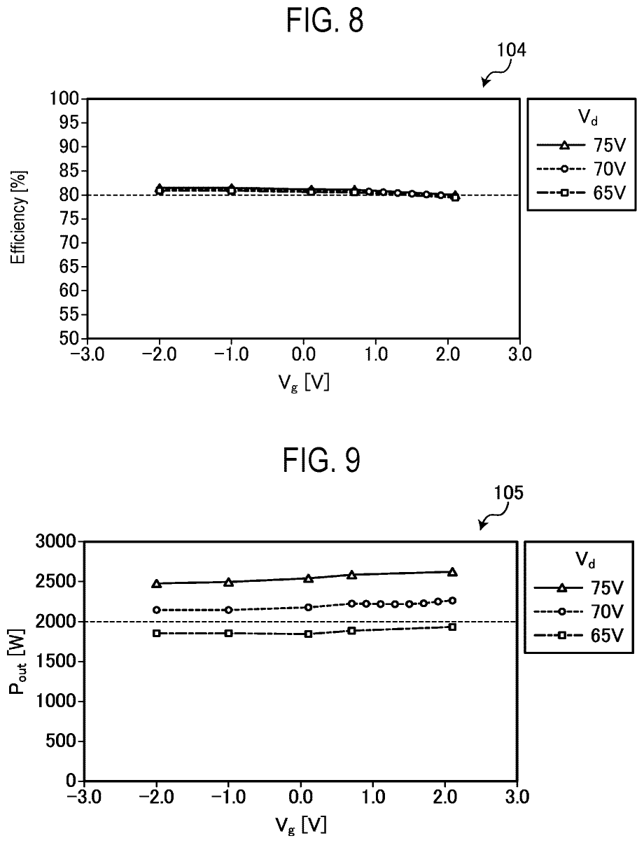

Next, calculation examples of parameters at 220 MHz which is a central frequency are described with reference to FIGS. 8 to 12. FIG. 8 is a graph illustrating an example of a relationship between gate voltages V_{g} and efficiencies with respect to drain voltages V_{d} at a central frequency. A graph 104 shown in FIG. 8 shows an example of a relationship between gate voltages V_{g} and efficiencies with respect to drain voltages V_{d} at the central frequency. For example, from the graph 104, it can be recognized that the efficiency becomes 80% or more if the gate voltage V_{g} is 1.7 V or lower even though the drain voltage V_{d} is any one of 65 V, 70 V, and 75 V.

FIG. 9 is a graph illustrating an example of a relationship between gate voltages V_{g} and outputs Pₒᵤₜ for maximum efficiency with respect to drain voltages V_{d} at the central frequency. A graph 105 shown in FIG. 9 shows an example of a relationship between gate voltages V_{g} and outputs Pₒᵤₜ for maximum efficiency with respect to drain voltages V_{d} at the central frequency. From the graph 105, it can be recognized that the output Pₒᵤₜ becomes 2000 W or more if the drain voltage V_{d} is 70 V or higher within a range in which the gate voltage V_{g} is-2.0 V to 2.2 V.

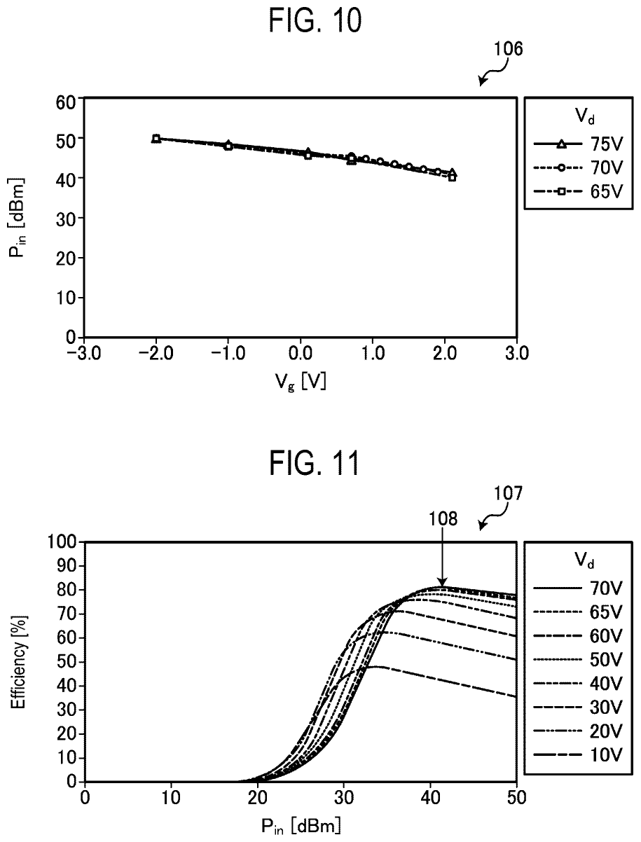

FIG. 10 is a graph illustrating an example of a relationship between gate voltages V_{g} and input powers Pᵢₙ for maximum efficiency with respect to drain voltages V_{d} at the central frequency. A graph 106 shown in FIG. 10 shows an example of a relationship between gate voltages V_{g} and input powers Pᵢₙ for maximum efficiency with respect to drain voltages V_{d} at the central frequency. From the graph 106, for example, when the drain voltage V_{d} is set to 70 V, a gate voltage V_{g} at which input power Pᵢₙ for maximum efficiency is lowest becomes 1.7 V within a range in which the gate voltage V_{g} is 1.7 V or lower. Here, the input power Pᵢₙ is set to a value as small as possible so as to suppress the input power Pᵢₙ from instantaneously exceeding rated power of the FET. Therefore, in 220 MHz, when the gate voltage V_{g} is 1.7 V and the drain voltage V_{d} is 70 V, the input power Pᵢₙ is obtained as 42.3 dBm from the graph 106.

FIG. 11 is a graph illustrating an example of a relationship between input powers Pᵢₙ and efficiencies with respect to drain voltages V_{d} at the central frequency. A graph 107 shown in FIG. 11 is when the gate voltage V_{g} is 1.7 V, and shows an example of a relationship between input powers Pᵢₙ and efficiencies with respect to drain voltages V_{d} at the central frequency. From the graph 107, it can be recognized that when the drain voltage V_{d} is 70 V and the input power Pᵢₙ is 42.3 dBm, maximum efficiency becomes about 80.2% as indicated by an arrow 108. Further, the graph 107 shows a relationship between input powers Pᵢₙ and efficiencies with respect to drain voltages V_{d} from 10 V to 65 V.

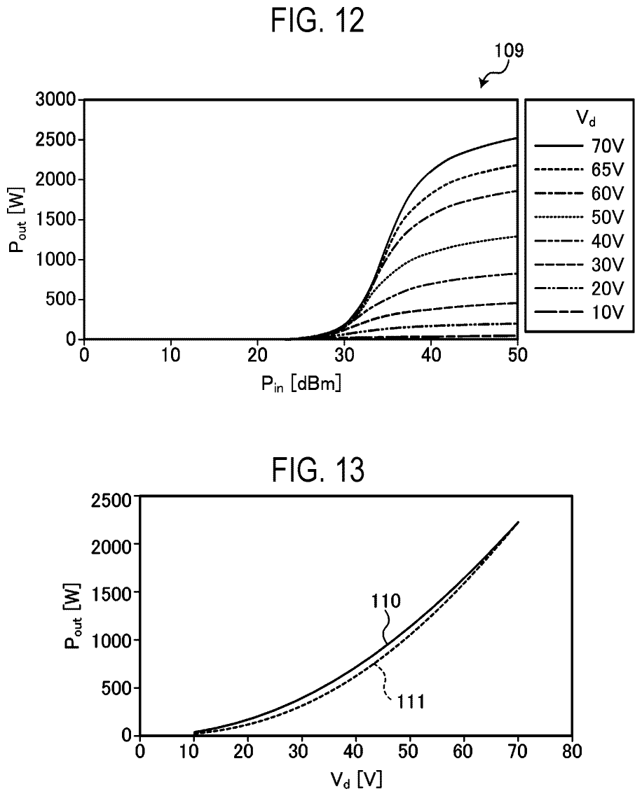

FIG. 12 is a graph illustrating an example of a relationship between input powers Pᵢₙ and outputs Pₒᵤₜ with respect to drain voltages V_{d} at the central frequency. A graph 109 shown in FIG. 12 is when the gate voltage V_{g} is 1.7 V, and shows an example of a relationship between input powers Pᵢₙ and outputs Pₒᵤₜ with respect to drain voltages V_{d} at the central frequency. From the graph 109, a relationship between drain voltages Vd and input powers Pᵢₙ when the output Pₒᵤₜ is set to 2000 W or more can be recognized.

### [Power Control According to Output]

Next, high-efficiency power control within a range of output Pₒᵤₜ, from low power to high power, is described with reference to FIGS. 13 to 15. FIG. 13 is a graph illustrating an example of a relationship between drain voltages V_{d} and outputs Pₒᵤₜ in a case where input power Pᵢₙ becomes constant and a case where the input power Pᵢₙ is set for maximum efficiency, at the central frequency. A graph 110 shown in FIG. 13 shows an example of a relationship between drain voltages V_{d} and outputs Pₒᵤₜ in a case where input power Pᵢₙ becomes constant. Meanwhile, a graph 111 shows and example of a relationship between drain voltages V_{d} and outputs Pₒᵤₜ in a case where the input power Pᵢₙ is set for maximum efficiency with respect to the drain voltages V_{d}. When comparing the graph 110 and the graph 111, the outputs Pₒᵤₜ are the same when the drain voltage V_{d} is 70 V, but a difference between the outputs Pₒᵤₜ occurs when the drain voltage V_{d} is lowered.

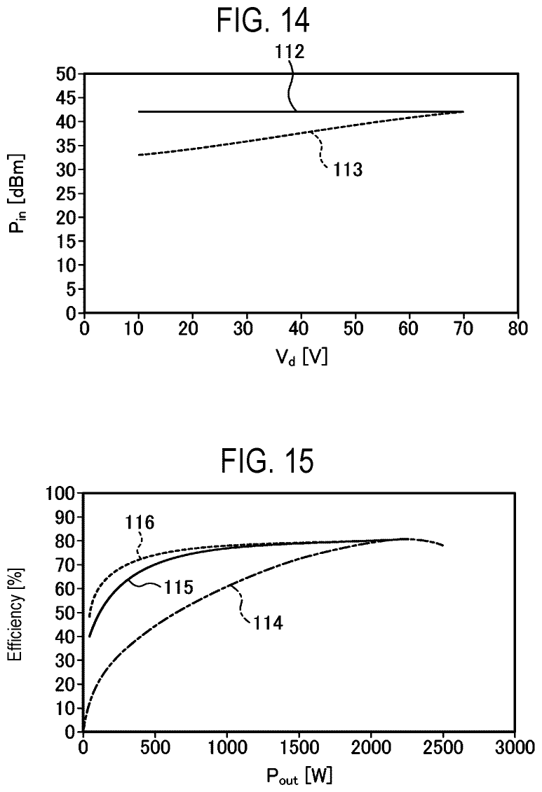

FIG. 14 is a graph illustrating an example of a relationship between drain voltages V_{d} and input power Pᵢₙ in a case where the input power Pᵢₙ becomes constant and a case where the radio-frequency power is set for maximum efficiency, at the central frequency. A graph 112 shown in FIG. 14 shows an example of a relationship between drain voltages V_{d} and input power Pᵢₙ in a case where the input power Pᵢₙ becomes constant. Meanwhile, a graph 113 shows an example of a relationship between drain voltages V_{d} and input power Pᵢₙ in a case where the input power Pᵢₙ is set for maximum efficiency with respect to the drain voltages V_{d}. That is, it can be recognized that the graph 113 shows input power Pᵢₙ corresponding to the graph 111 of FIG. 13, and the input power Pᵢₙ with which the radio-frequency power is set for maximum efficiency is changed depending on the drain voltages V_{d}.

FIG. 15 is a graph illustrating an example of a relationship between outputs Pₒᵤₜ and efficiencies in a case where drain voltage V_{d} and input power Pᵢₙ vary, at the central frequency. A graph 114 shown in FIG. 15 shows an example of a case where the drain voltage V_{d} is 70 V, and output Pₒᵤₜ is controlled by changing the input power Pᵢₙ. In graph 114, as the output Pₒᵤₜ becomes lower, the efficiency is reduced. A graph 115 shown in FIG. 15 shows an example of a case where the input power Pᵢₙ is 42.3 dBm, and the output Pₒᵤₜ is controlled by changing the drain voltage V_{d}. In graph 115, the efficiency is improved in a case where the output Pₒᵤₜ is low as compared with the case of the graph 114. A graph 116 shown in FIG. 15 shows an example of a case where the input power Pᵢₙ is controlled for maximum efficiency while controlling the output Pₒᵤₜ by changing the drain voltage V_{d}. In graph 116, the efficiency is improved when the output Pₒᵤₜ is low (e.g., a region of 1,000 W or less) when compared with the case of the graph 115. That is, the input power Pᵢₙ is controlled for maximum efficiency while controlling the output Pₒᵤₜ by changing the drain voltage V_{d}, thus enabling high-efficiency power control in a low output region.

### [Efficiency in Frequency Variation]

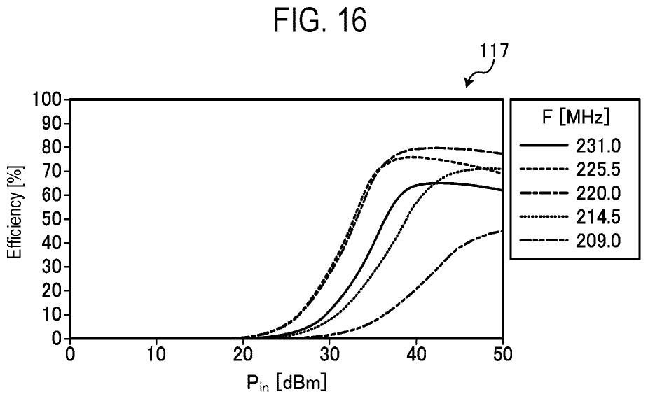

Next, a change in efficiency in frequency variation is described with reference to FIGS. 16 to 19. Further, in FIGS. 16 to 19, a drain voltage V_{d} is 70 V, and a gate voltage V_{g} is 1.7 V. FIG. 16 is a graph illustrating an example of a relationship between input powers Pᵢₙ and efficiencies in frequency variation. As shown in a graph 117 of FIG. 16, when a set frequency F is changed to 209.0 MHz, 214.5 MHz, 220.0 MHz, 225.5 MHz, and 231.0 MHz, a relationship between input power Pᵢₙ and efficiency is changed depending on a frequency. Further, as the set frequency F is spaced apart from 220.0 MHz, maximum efficiency is reduced.

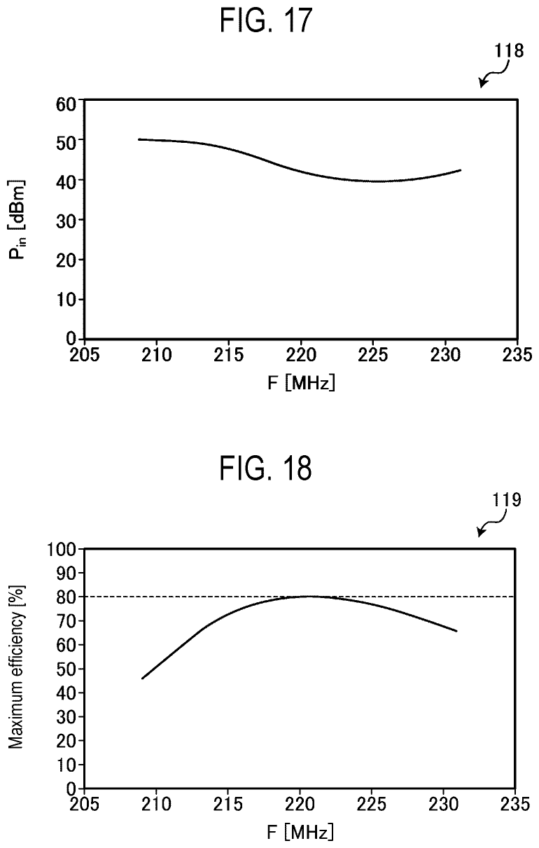

FIG. 17 is a graph illustrating an example of a relationship between frequencies and input powers Pᵢₙ. As shown in a graph 118 of FIG. 17, the input power Pᵢₙ for outputting rated power is increased at a set frequency F lower than 220 MHz which is a central frequency.

FIG. 18 is a graph illustrating an example of a relationship between frequencies and the maximum efficiency. In an example of a graph 119 shown in FIG. 18, the maximum efficiency is about 80.2% at 220 MHz which is a central frequency, but is reduced as a set frequency Fis spaced apart from 220 MHz. That is, the graph 119 shows maximum efficiency at each set frequency F in the graph 117 of FIG. 16, using the set frequency F as the horizontal axis. As such, in the main amp 65, the maximum efficiency is changed depending on frequencies. Therefore, the maximum efficiency is less than 80% in a case where the set frequency F is 209.0 MHz, 214.5 MHz, 225.5 MHz, and 231.0 MHz, but each parameter is adjusted such that output is set to maximum efficiency at each frequency.

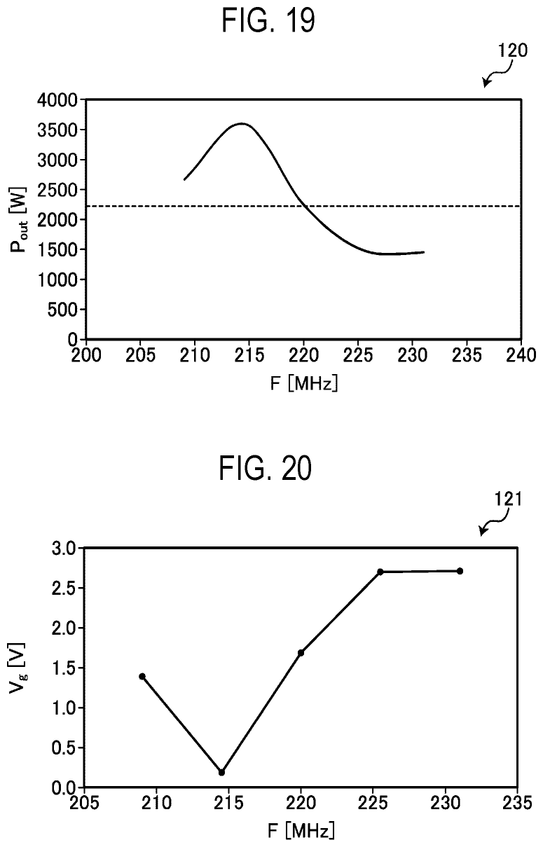

FIG. 19 is a graph illustrating an example of a relationship between frequencies and output Pₒᵤₜ. In an example of a graph 120 shown in FIG. 19, in a case where the output power Pₒᵤₜ is 2200 W at 220.0 MHz which is a central frequency, the output power Pₒᵤₜ is less than 2000 W in a case where set frequencies F are 225.5 MHz and 231.0 MHz. As such, in the main amp 65, the output power Pₒᵤₜ set for the maximum efficiency is changed depending on frequencies. Therefore, in a case where the set frequencies F are 225.5 MHz and 231.0 MHz, parameters are adjusted such that the output Pₒᵤₜ is 2,000 W or more, more preferably 2,200 W or more.

### [Calculation Example of Parameter in Frequency Variation]

Next, a calculation example of initial values of parameters in frequency variation is described with reference to FIGS. 20 to 25. Further, as for the calculation example of the parameters in the frequency variation, numerical analysis is performed using an advanced design system (ADS) as an example of a circuit simulator, but another circuit simulator may be used. In examples of FIGS. 20 to 25, 209.0 MHz, 214.5 MHz, 220.0 MHz, 225.5 MHz, and 231.0 MHz of the above-described set frequencies F are used as a plurality of discrete frequencies. That is, the following calculation example of the parameters is a generation example of initial values of the parameter table 100.

FIG. 20 is a graph illustrating an example of a relationship between frequencies and initial values of gate voltages V_{g}. A graph 121 shown in FIG. 20 shows an analysis result of gate voltages V_{g} with respect to set frequencies F. The analysis result of the graph 121 corresponds to the items of the gate voltages V_{g} in the tables 100 to 102 of FIGS. 4 to 6.

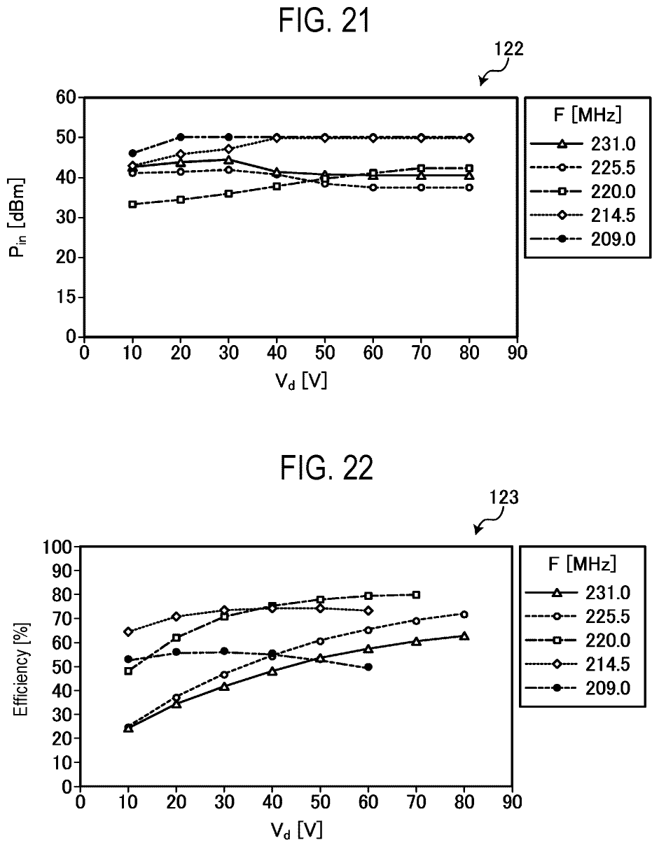

FIG. 21 is a graph illustrating an example of a relationship between drain voltages V_{d} and initial values of input powers Pᵢₙ with respect to frequencies. A graph 122 shown in FIG. 21 shows an analysis result of drain voltages V_{d} and input powers Pᵢₙ with respect to set frequencies F. The analysis result of the graph 122 corresponds to items of the input powers Pᵢₙ with respect to drain voltages V_{d} in the table 101 of FIG. 5. That is, the graph 122 is one obtained by graphing the drain voltages V_{d} and the input powers Pᵢₙ with respect to the set frequencies Fin the table 101.

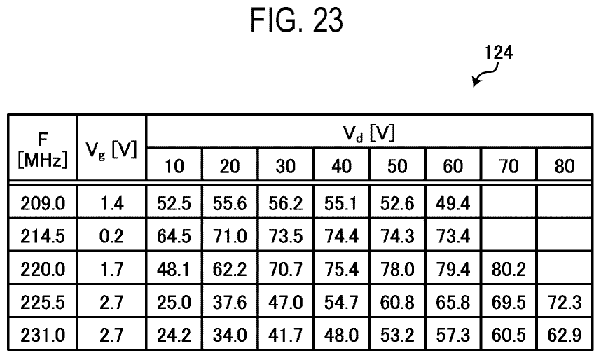

FIG. 22 is a graph illustrating an example of a relationship between drain voltages V_{d} and efficiencies with respect to frequencies. FIG. 23 is a view illustrating an example of a relationship between drain voltages V_{d} and efficiencies with respect to frequencies. A graph 123 of FIG. 22 and a table 124 of FIG. 23 show an analysis result of efficiencies in drain voltages V_{d} with respect to set frequencies F. That is, the graph 123 and the table 124 show estimation values of the maximum efficiency with respect to the set frequencies F and the drain voltages V_{d}. Further, the table 124 may include the parameter table 100.

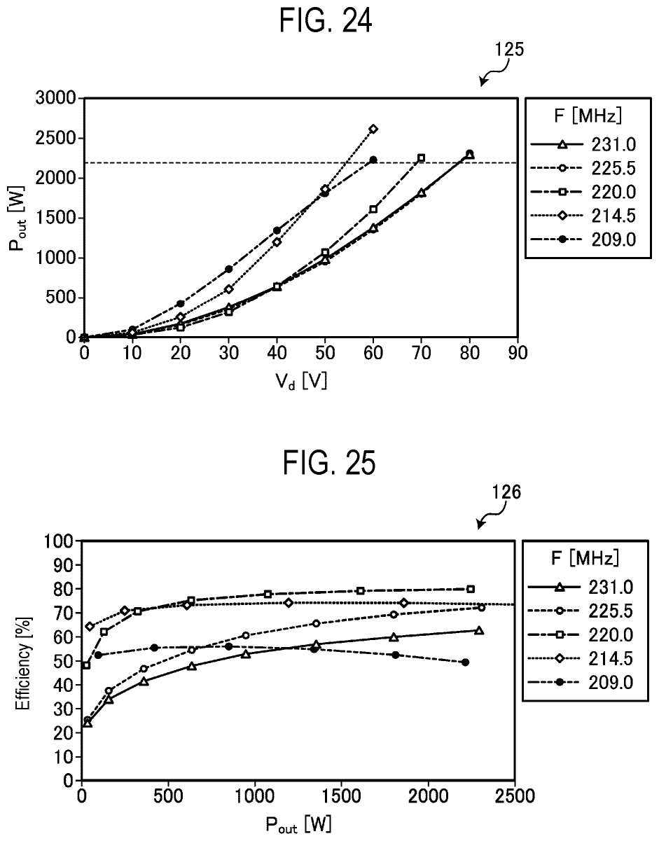

FIG. 24 is a graph illustrating an example of a relationship between drain voltages V_{d} and outputs Pₒᵤₜ with respect to frequencies. A graph 125 shown in FIG. 24 shows an analysis result of outputs Pₒᵤₜ in drain voltages V_{d} with respect to set frequencies F. The analysis result of the graph 125 corresponds to items of the outputs Pₒᵤₜ with respect to the drain voltages V_{d} in the table 102 of FIG. 6. That is, the graph 125 is one obtained by graphing the drain voltages V_{d} and the outputs Pₒᵤₜ with respect to the set frequencies F in the table 102. As shown in the graph 125, it can be recognized that the outputs Pₒᵤₜ at the set frequencies F exceed 2,200 W, which is an example of a target value, by adjusting the drain voltages V_{d}. That is, the main amp 65 may output radio-frequency power of 2200 W or more as estimation outputs at 209.0 MHz to 231.0 MHz, which is an example of an available output frequency band.

FIG. 25 is a graph illustrating an example of a relationship between outputs Pₒᵤₜ and efficiencies with respect to frequencies. A graph 126 shown in FIG. 25 shows an analysis result of efficiencies in outputs Pₒᵤₜ with respect to set frequencies F. The analysis result of the graph 126 is one obtained by graphing the graph 123 of FIG. 22 and the table 124 of FIG. 23, and the graph 125 of FIG. 24, using the efficiency as the vertical axis and the output Pₒᵤₜ as the horizontal axis. Further, the graph 126 may be tabled to include the parameter table 100.

### [Parameter Generation Method]

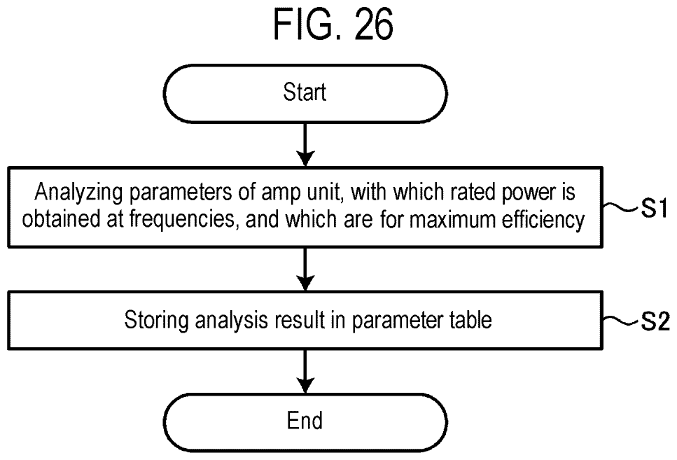

Next, a parameter generation method according to this embodiment is described. FIG. 26 is a flowchart illustrating an example of a parameter generation processing according to this embodiment.

The parameter generation processing according to this embodiment is performed in generation of the parameter table 100 pre-stored in the storage 72 of the first radio-frequency power source 60. That is, based on specifications of the first radio-frequency power source 60, the parameter generation processing is performed by an information processing device (not illustrated) which is connected to the first radio-frequency power source 60 via the upper controller 90. The information processing device stores the parameter table 100 in the storage 72 of the controller 70 of the first radio-frequency power source 60.

Based on the specifications of the first radio-frequency power source 60, the information processing device analyzes parameters of the amp unit (the main amp 65), allowing rated power to be obtained at frequencies in an available output frequency band, and those for maximum efficiency (step S1).

The information processing device stores an analysis result in the parameter table 100 of the storage 72 (step S2). Accordingly, the parameter table 100 may be generated. That is, as initial values of the parameter table 100, power monitoring values P_{fm} corresponding to a plurality of discrete set frequencies F, gate voltages V_{g}, drain voltages V_{d}, input powers Pᵢₙ, and set powers P_{f} in the available output frequency band may be set. Further, the parameters stored in the parameter table 100 may be set based on an actual measurement value.

### [Correction Value Generation Method]

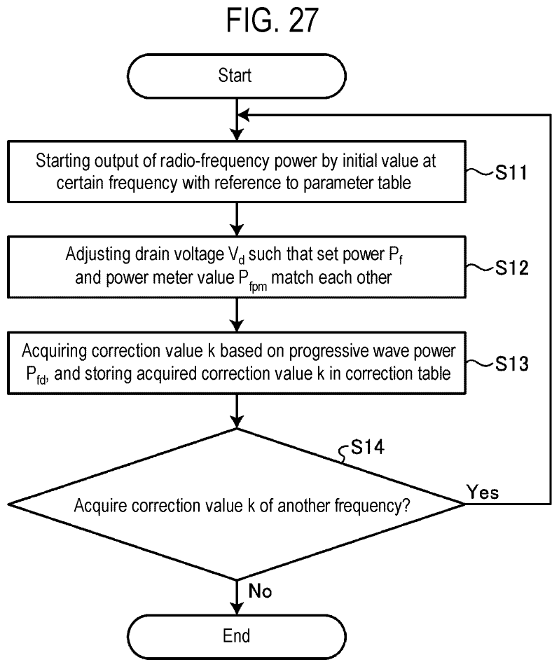

Next, a correction value generation method according to this embodiment is described. FIG. 27 is a flowchart illustrating an example of a correction value generation processing according to this embodiment.

The correction value generation processing according to this embodiment is performed in generation of the correction table 103 pre-stored in the storage 72 of the first radio-frequency power source 60. That is, as illustrated in FIG. 3, the correction value generation processing is performed by the controller 70 in a state in which the power meter 92 and the dummy load 93 are connected to the first radio-frequency power source 60. The controller 70 stores the correction table 103 in the storage 72. Further, the correction value generation processing may be performed by the upper controller 90 or may be performed by the controller 11 of the plasma processing apparatus 1. Further, the correction value generation processing may be performed by the information processing device (not illustrated) connected to the first radio-frequency power source 60 via the upper controller 90.

The controller 70 starts output of radio-frequency power by an initial value at a certain frequency with reference to the parameter table 100 stored in the storage 72 (step S11). For example, with respect to gate voltages V_{g}, drain voltages V_{d}, and input powers Pᵢₙ when the set frequency F is 220.0 MHz and the set power P_{f} is 2000 W, the controller 70 reads values when n of the parameter table 100 is “1” and values when n of the parameter table 100 is “2.” The controller 70 calculates a frequency set value Fₛₜ and an input power set value Vₚₐₛₜ in a case where the set power P_{f} is 2000 W by proportionally dividing the read values when n is “1” and read values when n is “2.” Similarly, the controller 70 calculates a drain voltage set value V_{dst} and a gate voltage set value V_{gst} in a case where the set power P_{f} is 2000 W by proportionally dividing the read values when n is “1” and read values when n is “2.” The controller 70 outputs the calculated set values as instruction values respectively to the DDS 61, the first variable DC voltage source 62, the second variable DC voltage source 64, and the buffer amp 66.

The controller 70 adjusts the drain voltages V_{d} such that the set power P_{f} and a power meter value P_{fpm} input from the power meter 92 match each other (step S12). That is, the controller 70 adjusts the drain voltage set value V_{dst} which is an instruction value for the second variable DC voltage source 64.

The controller 70 acquires a correction value k, based on progressive wave power P_{fd} converted from a progressive wave voltage V_{fd} input from the wave detector 68, in the state in which the set power P_{f} and the power meter value P_{fpm} match each other, and stores the acquired correction value k as a correction value k(Fₛₜ, n) at that time in the correction table 103 (step S13), using “P_{f}(n)=set power P_{f}”. For example, if the progressive wave power P_{fd} is 4000 W when the set power P_{f} is 2000 W and the power meter value P_{fpm} is 2000 W, the controller 70 calculates and stores a value satisfying “correction value k=P_{f}/P_{fd}=P_{fpm}/P_{fd}=2000/4000-0.5”. Specifically, the controller 70 stores each value of F(220, 1)=220, P_{f}(220, 1)=2000, and k(220, 1)=0.5 in the correction table 103 of the storage 72. Similarly, with respect to other set powers P_{f}, e.g., 1800 W, 1600 W, . . . , and 0 W, the controller 70 calculates a value that becomes a correction value k, and stores, in the correction table 103 of the storage 72, each value such as each value of F(220, 2)=220, P_{f}(220, 2)=1800, or k(220, 2)=0.56, and each value of F(220, 3)=220, P_{f}(220, 3)=1600, and k(220, 3)=0.64.

The controller 70 determines whether to acquire a correction value k of another frequency (step S14). When determining to acquire a correction value k of another frequency (step S14: “Yes”), the controller 70 returns to the step S11 to select one frequency among other frequencies, e.g., 209.0 MHz, 214.5 MHz, 225.5 MHz, and 231.0 MHz. Similarly, the controller 70 acquires a correction value k by starting output of radio-frequency power by an initial value at the selected frequency. Meanwhile, when determining not to acquire the correction value k of another frequency (step S14: “No”), the controller 70 stops the output of radio-frequency power and ends the correction value generation processing. Accordingly, it is possible to generate the correction table 103 at not only a central frequency but also other frequencies.

### [Power Control Method]

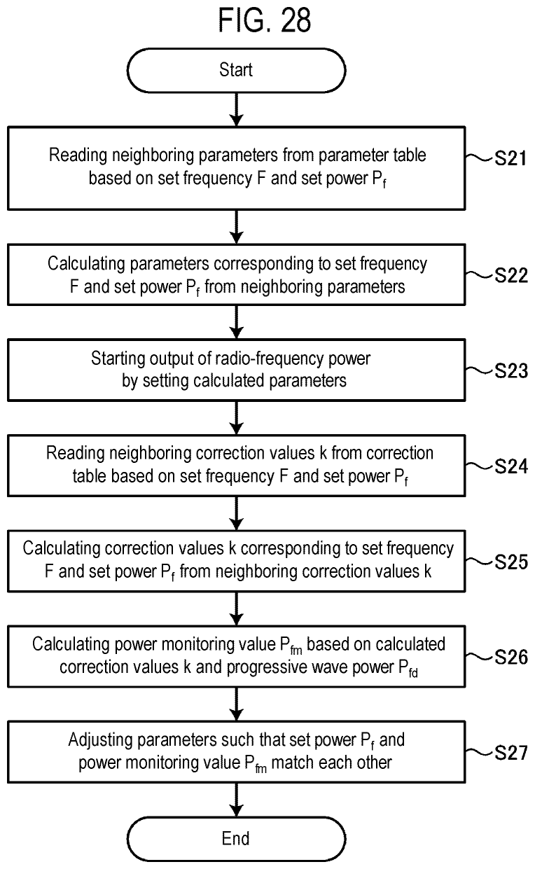

Next, a power control method according to this embodiment is described. FIG. 28 is a flowchart illustrating an example of a power control processing according to this embodiment.

The power control processing according to this embodiment is performed by the controller 70 of the first radio-frequency power source 60 according to an instruction of the controller 11 of the plasma processing apparatus 1. That is, in the plasma processing apparatus 1, the power control processing is performed by the controller 70 in a state in which the plasma load 91 is connected to the first radio-frequency power source 60 as illustrated in FIG. 2.

Further, the power control processing may be performed by the upper controller 90 or may be performed by the controller 11 of the plasma processing apparatus 1.

Based on a set frequency F and a set power P_{f}, which are input from the upper controller 90, the controller 70 reads neighboring parameters corresponding to the set frequency F and the set power P_{f} from the parameter table 100 of the storage 72 (step S21).

The controller 70 calculates parameters corresponding to the set frequency F and the set power P_{f} from the neighboring parameters (step S22). For example, when the set frequency Fis 220.0 MHz and the set power pr is 2000 W, the controller 70 reads a value when n is “1” and a value when n is “2,” in which power monitoring values P_{fm} are 2246 W and 1609 W in the table of 220.0 MHz of the parameter table 100. By proportionally dividing the read value when n is “1” and the read value when n is “2,” the controller 70 calculates each set value in a case where the set power P_{f} is 2000 W with respect to a gate voltage V_{g}, a drain voltage V_{d}, and input power Pᵢₙ.

The controller 70 starts output of radio-frequency power by setting the calculated parameters in the DDS 61, the first variable DC voltage source 62, the second variable DC voltage source 64, and the buffer amp 66 (step S23). That is, the controller 70 outputs, as instruction values, a frequency set value Fₛₜ, an input power set value Vₚₐₛₜ, a drain voltage set value V_{dst}, and a gate voltage set value V_{gst} to the DDS 61, the first variable DC voltage source 62, the second variable DC voltage source 64, and the buffer amp 66. Further, the controller 70 may perform load control in which power consumption in a load becomes constant by acquiring a reflected wave voltage V_{rd} and feeding the acquired reflected wave voltage V_{rd} back to each parameter such as a frequency set value Fₛₜ such that reflected wave power P_{rd} converted from the reflected wave voltage V_{rd} becomes lowest.

Based on the set frequency F and the set power P_{f}, the controller 70 reads a neighboring correction value k corresponding to the set frequency F and the set power P_{f} from the correction table 103 (step S24). The controller 70 calculates a correction value k corresponding to the set frequency F and the set power P_{f} from the neighboring correction value k (step S25).

The controller 70 calculates a power monitoring value P_{fm} based on the calculated correction value k and progressive wave power P_{fd} (step S26). The controller 70 adjusts the input power set value Vₚₐₛₜ and the drain voltage set value V_{dst}, which are respectively output to the first variable DC voltage source 62 and the second variable DC voltage source 64, such that the set power P_{f} and the power monitoring value P_{fm} match each other (step S27). That is, the controller 70 adjusts the parameters (the drain voltage Vd and the input power Pᵢₙ) such that the set power P_{f} and the power monitoring value P_{fm} match each other. Accordingly, it is possible to achieve both widening of a changeable frequency band and high efficiency in the frequency band.

### [Input Power Adjustment Method]

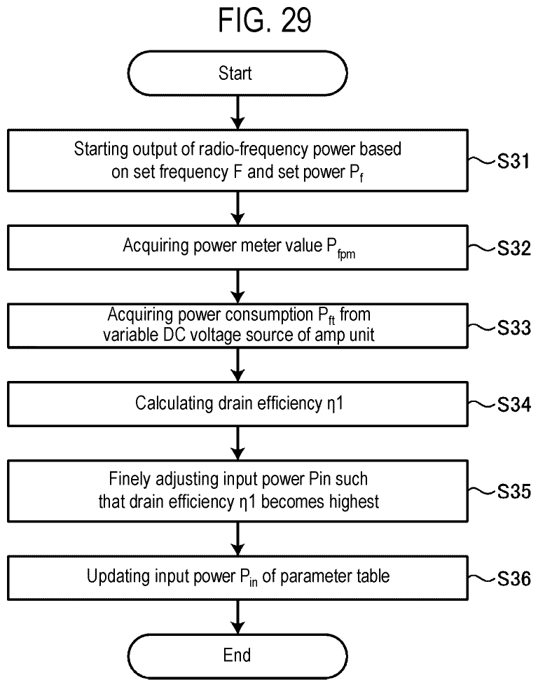

Next, an input power adjustment method of performing fine adjustment of input power Pᵢₙ according to this embodiment is described. FIG. 29 is a flowchart illustrating an example of an input power adjustment processing according to this embodiment.

The input power adjustment processing according to this embodiment is performed by the controller 70 of the first radio-frequency power source 60 according to an instruction of the controller 11 of the plasma processing apparatus 1. That is, in the plasma processing apparatus 1, the input power adjustment processing is performed by the controller 70 in a state in which the power meter 92 is interposed between the first radio-frequency power source 60 and the plasma load 91. Further, the input power adjustment processing may be performed by the controller 70 in a state in which the power meter 92 and the dummy load 93 are connected to the first radio-frequency power source 60. Further, input power adjustment processing may be performed by the upper controller 90 or may be performed by the controller 11 of the plasma processing apparatus 1.

The controller 70 starts output of radio-frequency power by performing the above-described power control processing (the steps S21 to S27) based on a set frequency F and set power P_{f}, which are input from the upper controller 90 (step S31).

The controller 70 acquires a power meter value P_{fpm} from the power meter 92 (step S32). The controller 70 acquires power consumption P_{ft} from the second variable DC voltage source 64 of the amp unit (step S33). Here, the power consumption P_{ft} acquired from the second variable DC voltage source 64 is one obtained by multiplying an FET drain voltage V_{d} and a drain current I_{d} of the main amp 65 as shown in the following equation (1).

$${P}_{ft} = {V}_{d} \times {I}_{d} \qquad ( 1 )$$

The controller 70 calculates drain efficiency η₁ of the FET of the main amp 65 by the following equation (2) based on output Pₒᵤₜ and the power consumption P_{ft} (step S34). Further, the output Pₒᵤₜ is the power meter value P_{fpm}, and is controlled as power monitoring value P_{fm}=power meter value P_{fpm}=output Pₒᵤₜ when a correction value k is stored by performing the correction value processing.

$${η}_{1} = {P}_{out} / {P}_{ft} \qquad ( 2 )$$

The controller 70 finely adjusts input power Pᵢₙ such that the drain efficiency η₁ becomes highest (step S35). That is, the controller 70 finely adjusts an input power set value Vₚₐₛₜ which is an instruction value of the first variable DC voltage source 62.

By the input power Pᵢₙ after the adjustment, the controller 70 updates input power Pᵢₙ corresponding to the parameter table 100 of the storage 72 (step S36). Accordingly, it is possible to adjust an individual difference of the FET of the main amp 65, and achieve both widening of a changeable frequency band and high efficiency in the frequency band. The above-described each processing is performed, so that when high efficiency of the output Pₒᵤₜ is achieved by suppressing a reflected wave (reflected wave power P_{rd}) through frequency tuning, a gate voltage V_{g} suitable for a frequency is employed, thereby satisfying rated power, and a drain voltage V_{d} is used as power feedback. Further, input power Pᵢₙ suitable for the drain voltage V_{d} is supplied to the FET (the main amp 65), so that it is possible to implement an amp operation in which high efficiency is achieved even though the frequency varies.

In addition to the drain efficiency η₁, in the input power adjustment processing, the input power Pᵢₙ may be finely adjusted such that power added efficiency η₂ or power source efficiency 13 becomes highest. That is, maximum efficiency is the drain efficiency η₁ of the amp unit (the main amp 65), the power added efficiency η₂, or the power source efficiency η₃. The power added efficiency η₂ and the power source efficiency η₃ may be calculated by the following equations (3) and (4), respectively. Further, the power added efficiency η₂ also represents as power added efficiency (PAE), and is a value obtained by subtracting the input power Pᵢₙ from the output Pₒᵤₜ in the drain efficiency η₁ and dividing the subtracted value by the power consumption P_{ft}. Further, the power source efficiency η₃ is conversion efficiency from the commercial power source in the first radio-frequency power source 60 to the entire power source of radio-frequency power. That is, the power source efficiency 13 becomes a value obtained by dividing the output Pₒᵤₜ by AC power P_{dc}.

$${η}_{2} = ( {P}_{out} - {P}_{in} ) / {P}_{ft} \qquad ( 3 )$$

$${η}_{3} = {P}_{out} / {P}_{ac} \qquad ( 4 )$$

In the above, according to this embodiment, the radio-frequency power source (the first radio-frequency power source 60) includes the amp unit (the main amp 65), the output terminal 74, the input power unit (the DDS 61, the first variable DC voltage source 62, and the preamp 63), the first setting unit (the buffer amp 66), the second setting unit (the second variable voltage source 64), and the instruction unit (the controller 70). The amp unit includes the gate terminal, the drain terminal, and the source terminal. The output terminal 74 is electrically connected to the drain terminal. The input power unit is electrically connected to the gate terminal, configured to supply input power Pᵢₙ to the amp unit, and configured to change frequencies in a frequency band in which the input powers Pᵢₙ can be supplied. The first setting unit is electrically connected to the gate terminal, and configured to set a gate bias voltage V_{g} of the amp unit. The second setting unit is electrically connected to the drain terminal, and configured to set a drain bias voltage V_{d} of the amp unit. The instruction unit is configured to output instruction values with which a radio-frequency power output from the output terminal 74 is set for maximum efficiency to the input power unit, the first setting unit, and the second setting unit with respect to each of the frequencies in the frequency band. As a result, it is possible to achieve high efficiency and widening of a frequency band.

Further, according to this embodiment, the amp unit is configured to operate by zero-cross switching. As a result, it is possible to improve efficiency of the amp unit.

Further, according to this embodiment, the instruction unit outputs instruction values to the input power unit, the first setting unit, and the second setting unit with reference to a storage unit (the storage 72 and the parameter table 100) that stores and correlates input powers Pᵢₙ with which the radio-frequency power is set for the maximum efficiency with the drain bias voltages V_{d}, respectively. As a result, it is possible to achieve both widening of a changeable frequency band and high efficiency in the frequency band.

Further, according to this embodiment, the instruction unit outputs instruction values to the input power unit, the first setting unit, and the second setting unit with reference to the storage unit (the storage 72 and the parameter table 100). The storage unit stores and correlates: frequencies (set frequencies F) of the input powers Pᵢₙ with gate bias voltages V_{g} with which the radio-frequency power is set to a target value or more with respect to the frequencies; a plurality of drain bias voltages V_{d}; input powers Pᵢₙ with which the radio-frequency power is set for the maximum efficiency with respect to the drain bias voltages V_{d}; and set powers (power monitoring values P_{fm} corresponding to set powers P_{f}) of the radio-frequency power, which correspond to the input powers Pᵢₙ, respectively. As a result, it is possible to achieve both widening of a changeable frequency band and high efficiency in the frequency band.

Further, according to this embodiment, the instruction unit calculates the instruction values for the input power unit, the first setting unit, and the second setting unit by performing proportional division from frequencies, gate bias voltages V_{g}, drain bias voltages V_{d}, input powers Pᵢₙ, and set powers, which are stored as discrete values in the storage unit, and outputs the calculated instruction values. As a result, it is possible to output instruction values of the gate bias voltages V_{g}, the drain bias voltages V_{d}, and the input powers Pᵢₙ even with respect to frequencies that do not exist in the parameter table 100.

Further, according to this embodiment, the radio-frequency power source includes the directional coupler 67 provided between the drain terminal and the output terminal 74. The storage unit (the storage 72 and the correction table 103) stores and correlates correction values k of the radio-frequency power with frequencies of input powers and a plurality of set powers P_{f} of radio-frequency power, respectively. Referencing the storage unit, the instruction unit calculates a power monitoring value P_{fm}, based on progressive waves (progressive wave power P_{fd}) output from the directional coupler 67 and the correction values k, and outputs instruction values to the input power unit and the second setting unit such that the calculated power monitoring value P_{fm} and a current set power Prof radio-frequency power match each other. As a result, it is possible to correct characteristics of a frequency and power of the directional coupler 67.

Further, according to this embodiment, the instruction unit calculates instruction values for the input power unit and the second setting unit by performing proportional division from frequencies, set powers P_{f}, and correction values k, which are stored as discrete values in the storage unit, and outputs the calculated instruction values. As a result, it is possible to output instruction values of the drain bias voltages V_{d} and the input powers Pᵢₙ even with respect to frequencies that do not exist in the correction table 103.

Further, according to this embodiment, the maximum efficiency is drain efficiency of the amp unit, power added efficiency, or power source efficiency. As a result, it is possible to set efficiency of the interior of the first radio-frequency power source 60 or the whole to the maximum efficiency.

Further, according to this embodiment, the radio-frequency power source (the first radio-frequency power source 60) is a radio-frequency power source that output radio-frequency power of specific frequency (set frequency F) in an available output frequency band, and includes the switching amplification circuit (the main amp 65) and the controller 70 that controls parameters of the switching amplification circuit such that in a frequency band, radio-frequency power is set to a target value or more for each specific frequency. As a result, it is possible to achieve both high efficiency and widening of a frequency band.

Further, according to this embodiment, the switching amplification circuit includes a transistor including a gate terminal, a drain terminal, and a source terminal. Parameters are input powers Pᵢₙ, gate bias voltages V_{g}, and drain bias voltages V_{d} of the transistor. As a result, it is possible to achieve both high efficiency and widening of a frequency band.

Further, according to this embodiment, with reference to the storage unit (the storage 72 and the parameter table 100) that stores and correlates input powers Pᵢₙ with which the radio-frequency power is set for the maximum efficiency with drain bias voltages V_{d}, respectively, the controller 70 controls the input power Pᵢₙ, the gate bias voltages V_{g}, and the drain bias voltages V_{d}. As a result, it is possible to achieve both widening of a changeable frequency band and high efficiency in the frequency band.

The embodiments disclosed herein should be considered to be exemplary and not limitative in all respects. The above embodiments may be omitted, replaced, and modified in various ways without departing from the scope and spirit of the appended claims.

In addition, in the above-described embodiment, the plasm processing apparatus 1 that performs a processing such as etching on the substrate W, using capacitively coupled plasma as a plasma source, has been described as an example, but the disclosed technique is not limited thereto. As long as the plasma processing apparatus 1 is an apparatus that performs a processing on the substrate W and uses a radio-frequency power source, the plasma source is not limited to the capacitively coupled plasma, and for example, an arbitrary plasma source such as inductively coupled plasma, microwave plasma, or magnetron plasma may be used.

In addition, the present disclosure may have a configuration as follows.
(1) A radio-frequency power source, including:
   an amp unit including a gate terminal, a drain terminal, and a source terminal;
   an output terminal electrically connected to the drain terminal;
   an input power unit electrically connected to the gate terminal, configured to supply an input power to the amp unit, and configured to change frequencies in a frequency band in which the input power is can be supplied;
   a first setting unit electrically connected to the gate terminal, and configured to set a gate bias voltage of the amp unit;
   a second setting unit electrically connected to the drain terminal, and configured to set a drain bias voltage of the amp unit; and
   an instruction unit configured to output instruction values with which a radio-frequency power output from the output terminal is set for maximum efficiency to the input power unit, the first setting unit, and the second setting unit with respect to each of the frequencies in the frequency band.
(2) The radio-frequency power source of (1), wherein the amp unit is configured to operate by zero-cross switching.
(3) The radio-frequency power source of (1) or (2), wherein the instruction unit outputs the instruction values to the input power unit, the first setting unit, and the second setting unit with reference to a storage unit that stores and correlates the input powers with which the radio-frequency power is set for the maximum efficiency with the drain bias voltages, respectively.
(4) The radio-frequency power source of (3), wherein the instruction unit outputs the instruction values to the input power unit, the first setting unit, and the second setting unit with reference to the storage unit, and
   wherein the storage unit stores and correlates:
   the frequencies of the input powers with the gate bias voltages with which the radio-frequency power is set to a target value or more with respect to the frequencies; the drain bias voltages; the input powers with which the radio-frequency power is set for the maximum efficiency with respect to the drain bias voltages; and set powers of the radio-frequency power, which correspond to the input powers, respectively.
(5) The radio-frequency power source of (4), wherein the instruction unit calculates the instruction values for the input power unit, the first setting unit, and the second setting unit by performing proportional division from the frequencies, the gate bias voltages, the drain bias voltages, the input powers, and the set powers, which are stored as discrete values in the storage unit, and outputs the calculated instruction values.
(6) The radio-frequency power source of any one of (1) to (5), further including a directional coupler provided between the drain terminal and the output terminal,
   wherein a storage unit stores and correlates correction values of the radio-frequency power with the frequencies of the input powers and set powers of the radio-frequency power, respectively, and
   wherein, referencing the storage unit, the instruction unit calculates a power monitoring value based on progressive waves output from the directional coupler and the correction values, and outputs the instruction values to the input power unit and the second setting unit such that the calculated power monitoring value and a current set power of the radio-frequency power match each other.
(7) The radio-frequency power source of (6), wherein the instruction unit calculates the instruction values for the input power unit and the second setting unit by performing proportional division from the frequencies, the set powers, and the correction values, which are stored as discrete values in the storage unit, and outputs the calculated instruction values.
(8) The radio-frequency power source of any one of (1) to (7), wherein the maximum efficiency is drain efficiency of the amp unit, power added efficiency, or power source efficiency.
(9) A radio-frequency power source that outputs a radio-frequency power of specific frequency in an available output frequency band, including:
   a switching amplification circuit; and
   a controller configured to control parameters of the switching amplification circuit such that the radio-frequency power is set to a target value or more with respect to the specific frequencies in the frequency band.
(10) The radio-frequency power source of (9), wherein the switching amplification circuit includes a transistor including a gate terminal, a drain terminal, and a source terminal, and
   wherein the parameters are input powers, gate bias voltages, and drain bias voltages of the transistor.
(11) The radio-frequency power source of (10), wherein, with reference to a storage unit that stores and correlates the input powers with which the radio-frequency power is set for maximum efficiency with the drain bias voltages, respectively, the controller controls the input powers, the gate bias voltages, and the drain bias voltages.
(12) A plasma processing apparatus, including:
   a processing container;
   an electrode provided inside the processing container; and
   a radio-frequency power source configured to output radio-frequency waves of a set frequency to the electrode,
   wherein the radio-frequency power source includes:
      an amp unit including a gate terminal, a drain terminal, and a source terminal;
      an output terminal electrically connected to the electrode and the drain terminal;
      an input power unit electrically connected to the gate terminal, configured to supply an input power to the amp unit, and configured to change frequencies in a frequency band in which the input power can be supplied;
      a first setting unit electrically connected to the gate terminal, and configured to set gate a bias voltage of the amp unit;
      a second setting unit electrically connected to the drain terminal, and configured to set a drain bias voltage of the amp unit; and
      an instruction unit configured to output instruction values with which a radio-frequency power output from the output terminal is set for maximum efficiency to the input power unit, the first setting unit, and the second setting unit with respect to each of the frequencies in the frequency band.

According to the present disclosure in some embodiments, it is possible to achieve both high efficiency and widening of a frequency band.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A radio-frequency power source, comprising:
an amp unit including a gate terminal, a drain terminal, and a source terminal;
an output terminal electrically connected to the drain terminal;
an input power unit electrically connected to the gate terminal, configured to supply an input power to the amp unit, and configured to change frequencies in a frequency band in which the input power is can be supplied;
a first setting unit electrically connected to the gate terminal, and configured to set a gate bias voltage of the amp unit;
a second setting unit electrically connected to the drain terminal, and configured to set a drain bias voltage of the amp unit; and
an instruction unit configured to output instruction values with which a radio-frequency power output from the output terminal is set for maximum efficiency to the input power unit, the first setting unit, and the second setting unit with respect to each of the frequencies in the frequency band.

2. The radio-frequency power source of claim 1, wherein the amp unit is configured to operate by zero-cross switching.

3. The radio-frequency power source of claim 2, wherein the instruction unit outputs the instruction values to the input power unit, the first setting unit, and the second setting unit with reference to a storage unit that stores and correlates the input powers with which the radio-frequency power is set for the maximum efficiency with the drain bias voltages, respectively.

4. The radio-frequency power source of claim 3, wherein the instruction unit outputs the instruction values to the input power unit, the first setting unit, and the second setting unit with reference to the storage unit, and
wherein the storage unit stores and correlates:
the frequencies of the input powers with the gate bias voltages with which the radio-frequency power is set to a target value or more with respect to the frequencies; the drain bias voltages; the input powers with which the radio-frequency power is set for the maximum efficiency with respect to the drain bias voltages; and set powers of the radio-frequency power, which correspond to the input powers, respectively.

5. The radio-frequency power source of claim 4, wherein the instruction unit calculates the instruction values for the input power unit, the first setting unit, and the second setting unit by performing proportional division from the frequencies, the gate bias voltages, the drain bias voltages, the input powers, and the set powers, which are stored as discrete values in the storage unit, and outputs the calculated instruction values.

6. The radio-frequency power source of claim 2, further comprising a directional coupler provided between the drain terminal and the output terminal,
wherein a storage unit stores and correlates correction values of the radio-frequency power with the frequencies of the input powers and set powers of the radio-frequency power, respectively, and
wherein, referencing the storage unit, the instruction unit calculates a power monitoring value based on progressive waves output from the directional coupler and the correction values, and outputs the instruction values to the input power unit and the second setting unit such that the calculated power monitoring value and a current set power of the radio-frequency power match each other.

7. The radio-frequency power source of claim 6, wherein the instruction unit calculates the instruction values for the input power unit and the second setting unit by performing proportional division from the frequencies, the set powers, and the correction values, which are stored as discrete values in the storage unit, and outputs the calculated instruction values.

8. The radio-frequency power source of claim 2, wherein the maximum efficiency is drain efficiency of the amp unit, power added efficiency, or power source efficiency.

9. The radio-frequency power source of claim 1, wherein the instruction unit outputs the instruction values to the input power unit, the first setting unit, and the second setting unit with reference to a storage unit that stores and correlates the input powers with which the radio-frequency power is set for the maximum efficiency with the drain bias voltages, respectively.

10. The radio-frequency power source of claim 1, further comprising a directional coupler provided between the drain terminal and the output terminal,
wherein a storage unit stores and correlates correction values of the radio-frequency power with the frequencies of the input powers and set powers of the radio-frequency power, respectively, and
wherein, referencing the storage unit, the instruction unit calculates a power monitoring value based on progressive waves output from the directional coupler and the correction values, and outputs the instruction values to the input power unit and the second setting unit such that the calculated power monitoring value and a current set power of the radio-frequency power match each other.

11. The radio-frequency power source of claim 1, wherein the maximum efficiency is drain efficiency of the amp unit, power added efficiency, or power source efficiency.

12. A radio-frequency power source that outputs a radio-frequency power of specific frequency in an available output frequency band, comprising:
a switching amplification circuit; and
a controller configured to control parameters of the switching amplification circuit such that the radio-frequency power is set to a target value or more with respect to the specific frequencies in the frequency band.

13. The radio-frequency power source of claim 12, wherein the switching amplification circuit includes a transistor including a gate terminal, a drain terminal, and a source terminal, and
wherein the parameters are input powers, gate bias voltages, and drain bias voltages of the transistor.

14. The radio-frequency power source of claim 13, wherein, with reference to a storage unit that stores and correlates the input powers with which the radio-frequency power is set for maximum efficiency with the drain bias voltages, respectively, the controller controls the input powers, the gate bias voltages, and the drain bias voltages.

15. A plasma processing apparatus, comprising:
a processing container;
an electrode provided inside the processing container; and
a radio-frequency power source configured to output radio-frequency waves of a set frequency to the electrode,
wherein the radio-frequency power source includes:
an amp unit including a gate terminal, a drain terminal, and a source terminal;
an output terminal electrically connected to the electrode and the drain terminal;
an input power unit electrically connected to the gate terminal, configured to supply an input power to the amp unit, and configured to change frequencies in a frequency band in which the input power can be supplied;
a first setting unit electrically connected to the gate terminal, and configured to set gate a bias voltage of the amp unit;
a second setting unit electrically connected to the drain terminal, and configured to set a drain bias voltage of the amp unit; and
an instruction unit configured to output instruction values with which a radio-frequency power output from the output terminal is set for maximum efficiency to the input power unit, the first setting unit, and the second setting unit with respect to each of the frequencies in the frequency band.
